(19) United States
(12) Patent Application Publication
(10) Pub. No.: US 2026/0142603 A1
(43) Pub. Date: May 21, 2026

(54) SYSTEMS, APPARATUSES, AND METHODS FOR FAULT ACCOMMODATION FOR MOTOR CONTROL

(71) Applicant: Siemens Healthineers Endovascular Robotics, Inc., Newton, MA (US)

(72) Inventors: Nicholas Kottenstette, Sterling, MA (US); Kody Saeedi, Ashland, MA (US)

(21) Appl. No.: 18/954,610

(22) Filed: Nov. 21, 2024

(51) Int. Cl. H02P 29/024; G01R 31/34; G01R 31/52

(52) U.S. Cl. CPC H02P 29/024; G01R 31/34; G01R 31/52

(57) ABSTRACT

A system for fault accommodation in a motor includes at least one memory and at least one processor. The at least one memory is configured to store instructions and the at least one processor is configured to execute the instructions and cause the system to determine an estimated angular velocity of the motor and an estimated angular position of the motor, detect a sensor fault of the motor encoder, and in response to the sensor fault being detected, detect at least one additional fault with at least one of the estimated angular velocity or the estimated angular position.

### TECHNICAL FIELD

The present disclosure relates to systems, apparatuses, and methods for fault accommodation for motor control.

### BACKGROUND

Catheters and other elongated medical devices (EMDs) may be used for minimally-invasive medical procedures for diagnosing and/or treating diseases of various vascular systems. Example medical procedures include neurovascular intervention (NVI) also known as neurointerventional surgery, percutaneous coronary intervention (PCI) and peripheral vascular intervention (PVI). These procedures typically involve navigating a guidewire through the vasculature to advance a catheter to deliver therapy. Robotic catheter-based procedure systems may be used to aid a physician in performing medical procedures such as those mentioned above.

One or more motors may be included in a system configured to perform robotic catheter-based procedures. One or more sensors may be configured to monitor parameters of the motor during performance of the robotic catheter-based procedures.

### SUMMARY

At least one example embodiment relates to a system for fault accommodation in a motor. The system may include at least one memory configured to store instructions and at least one processor. The at least one processor may be configured to execute the instructions and cause the system to determine an estimated angular velocity of the motor and an estimated angular position of the motor, detect a sensor fault of the motor encoder, and in response to the sensor fault being detected, detect at least one additional fault with at least one of the estimated angular velocity or the estimated angular position.

In at least one example embodiment, the at least one processor may be further configured to cause the system to determine an estimated coil resistance of the motor based on a measured motor coil temperature and an ambient temperature. In at least one example embodiment, the estimated angular velocity may be a first estimated angular velocity. The first estimated angular velocity may be determined based on the estimated coil resistance of the motor, a measured motor voltage, a measured motor current, a filtered motor current, and an inductance.

In at least one example embodiment, the at least one processor may be further configured to cause the system to obtain a sensed angular velocity of the motor and a sensed angular position of the motor. In at least one example embodiment, the at least one processor may be further configured to cause the system to determine an angular velocity residual based on the sensed angular velocity of the motor and the estimated angular velocity of the motor and determine an angular position residual based on the sensed angular position of the motor encoder and the estimated angular position of the motor encoder. In at least one example embodiment, the motor encoder may include a first pin, a second pin, and an index pin. The system may be further configured to detect an electrical fault based on a state of one or more of the first pin, the second pin, or the index pin. In at least one example embodiment, the estimated angular velocity is a second estimated angular velocity. The second estimated angular velocity may be determined based on a measured current and a model of a motor plant in response to an electrical fault being detected. In at least one example embodiment, the at least one additional fault is a fault state of the motor encoder. The fault state of the motor encoder may be detected based on the angular velocity residual or detection of the electrical fault. In at least one example embodiment, the estimated angular position of the motor encoder is used for motor position and velocity control in response to the at least one additional fault being a fault state of the motor encoder. In at least one example embodiment, the at least one processor may be further configured to cause the system to set a minimum velocity as a threshold for detecting motion of the motor and determine a selected angular velocity when no motion of the motor is detected. In at least one example embodiment, the selected angular velocity is the estimated angular velocity in response to determining that the motor encoder is broken and is the sensed angular velocity in response to the sensed angular velocity agreeing with the estimated angular velocity.

In at least one example embodiment, the at least one processor may be further configured to cause the system to determine a current residual based on a sensed current and an estimated current of the motor. In at least one example embodiment, the at least one additional fault is an open circuit. The open circuit may be detected based on the current residual, a minimum allowable angular velocity threshold, and a motor resistance fault. In at least one example embodiment, the at least one additional fault is a short circuit. The short circuit may be detected based on the current residual and a motor resistance fault.

In at least one example embodiment, the motor may be a direct current (“DC”) motor.

In at least one example embodiment, the estimated angular velocity may be independent of loads applied in the system.

Also described herein is a method for fault accommodation in a motor. The method may include determining an estimated angular velocity of the motor and an estimated angular position of the motor, detecting a sensor fault of the motor encoder, and in response to the sensor fault being detected, detecting at least one additional fault with at least one of the estimated angular velocity or the estimated angular position.

In at least one example embodiment, the method may further include determining an estimated coil resistance of the motor based on a measured motor coil temperature and an ambient temperature. In at least one example embodiment, the estimated angular velocity may be a first estimated angular velocity. The first estimated angular velocity may be determined based on the estimated coil resistance of the motor, a measured motor voltage, a measured motor current, a filtered motor current, and an inductance.

In at least one example embodiment, the method may further include obtaining a sensed angular velocity of the motor and a sensed angular position of the motor, determining an angular velocity residual based on the sensed angular velocity of the motor and the estimated angular velocity of the motor and determining an angular position residual based on the sensed angular position of the motor encoder and the estimated angular position of the motor encoder. In at least one example embodiment, the motor encoder may include a first pin, a second pin, and an index pin. The method may further include detecting an electrical fault based on a state of one or more of the first pin, the second pin, or the index pin. In at least one example embodiment, the estimated angular velocity is a second estimated angular velocity. The second estimated angular velocity may be determined based on a measured current and a model of a motor plant in response to an electrical fault being detected. In at least one example embodiment, the at least one additional fault is a fault state of the motor encoder. The fault state of the motor encoder may be detected based on the angular velocity residual or detection of the electrical fault. In at least one example embodiment, the estimated angular position of the motor encoder may be used for motor position and velocity control in response to the at least one additional fault being a fault state of the motor encoder. In at least one example embodiment, the method may further include setting a minimum velocity as a threshold for detecting motion of the motor and determining a selected angular velocity when no motion of the motor is detected. In at least one example embodiment, the selected angular velocity is the estimated angular velocity in response to determining that the motor encoder is broken and is the sensed angular velocity in response to the sensed angular velocity agreeing with the estimated angular velocity.

In at least one example embodiment, the method may further include determining a current residual based on a sensed current and an estimated current of the motor. In at least one example embodiment, the at least one additional fault is an open circuit. The open circuit may be detected based on the current residual, a minimum allowable angular velocity threshold, and a motor resistance fault. In at least one example embodiment, the at least one additional fault is a short circuit. The short circuit may be detected based on the current residual and a motor resistance fault.

In at least one example embodiment, the motor may be a direct current (“DC”) motor.

In at least one example embodiment, the estimated angular velocity may be independent of loads applied in the system.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1 is a side, perspective view of a treatment system according to at least one example embodiment.

FIG. 2A is a block diagram of the treatment system of FIG. 1 according to at least one example embodiment.

FIG. 2B is a block diagram of the memory of the treatment system of FIG. 2 according to at least one example embodiment.

FIG. 3 is an illustration of a DC motor gearbox encoder assembly according to at least one example embodiment.

FIG. 4 is a diagram of a DC motor angular velocity residual generator according to at least one example embodiment.

FIG. 5 is a logic diagram of a motor encoder electrical fault detector according to at least one example embodiment.

FIG. 6 is a diagram of an output of a first pin and a second pin of a motor encoder according to at least one example embodiment.

FIG. 7A is a state diagram of decoding a quadrature encoder to increment or decrement a counter according to at least one example embodiment.

FIG. 7B is a flow chart of an algorithm used to determine if a motor is moving according to at least one example embodiment.

FIG. 8 is a diagram of a DC motor resistance fault detector according to at least one example embodiment.

FIG. 9 a diagram of a mechanical omega estimator according to at least one example embodiment.

FIG. 10 is a diagram of an angular velocity selector according to at least one example embodiment.

FIG. 11 is a diagram of a discrete time motor temperature system that is used to estimate a motor coil resistance according to at least one example embodiment.

FIG. 12 is a diagram of a DT second order motor temperatures model according to at least one example embodiment.

FIG. 13 is a diagram of a motor fault detection and accommodation function according to at least one example embodiment.

### DETAILED DESCRIPTION OF EXAMPLE EMBODIMENTS

Independent of the grammatical term usage, individuals with male, female or other gender identities are included within the term.

Some detailed example embodiments are disclosed herein. However, specific structural and functional details disclosed herein are merely representative for purposes of describing some example embodiments. Example embodiments may, however, be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit an example embodiment to the particular forms disclosed, but to the contrary, example embodiments are to cover all modifications, combinations, equivalents, and alternatives falling within the scope of an example embodiment. Like numbers refer to like elements throughout the description of the figures.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiment.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various example embodiment only and is not intended to be limiting of example embodiment. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, and/or elements, but do not preclude the presence or addition of one or more other features, integers, steps, operations, elements and/or groups thereof.

Example embodiments are described herein with reference to cross-sectional illustrations that are schematic illustrations of example embodiment. As such, variations from the shapes of the illustrations are to be expected. Thus, example embodiment should not be construed as limited to the shapes of regions illustrated herein but are to include deviations and variations in shapes.

When the words “about” and “substantially” are used in this specification in connection with a numerical value, it is intended that the associated numerical value include a tolerance of ±10% around the stated numerical value, unless otherwise explicitly defined. Moreover, when the terms “generally” or “substantially” are used in connection with geometric shapes, it is intended that precision of the geometric shape is not required but that latitude for the shape is within the scope of the disclosure. Furthermore, regardless of whether numerical values or shapes are modified as “about,” “generally,” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which example embodiment belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

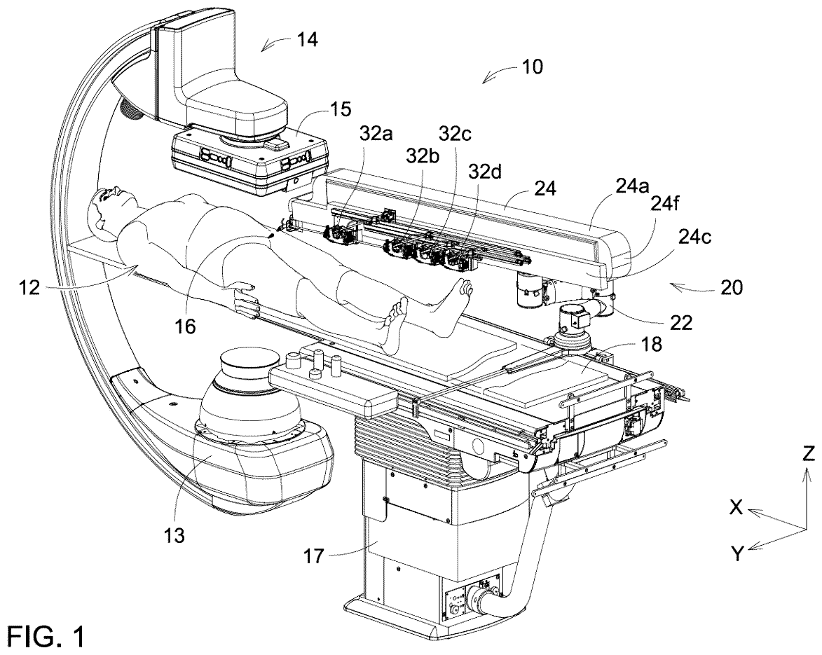

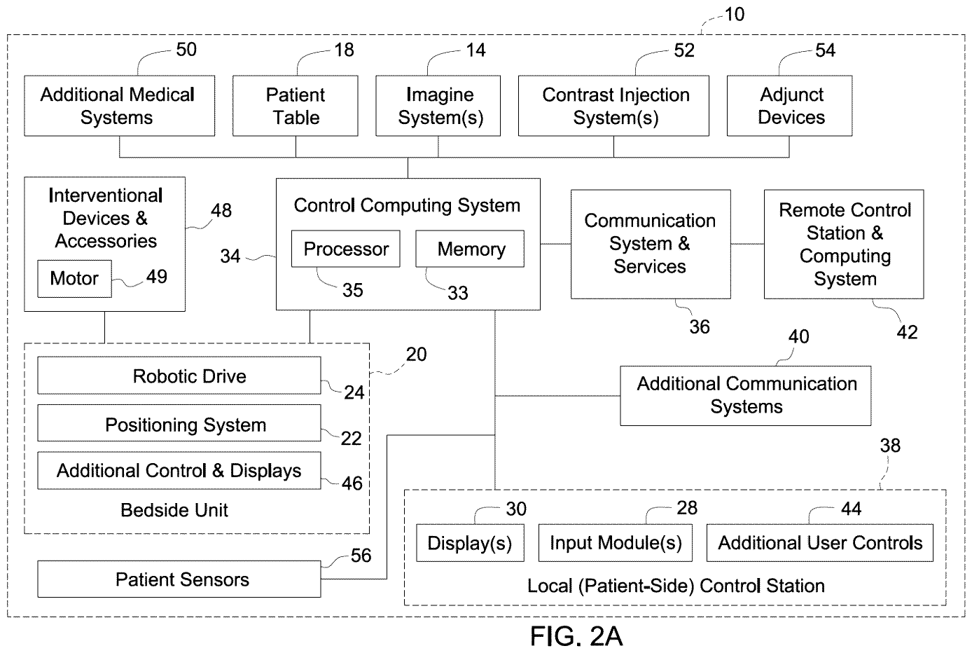

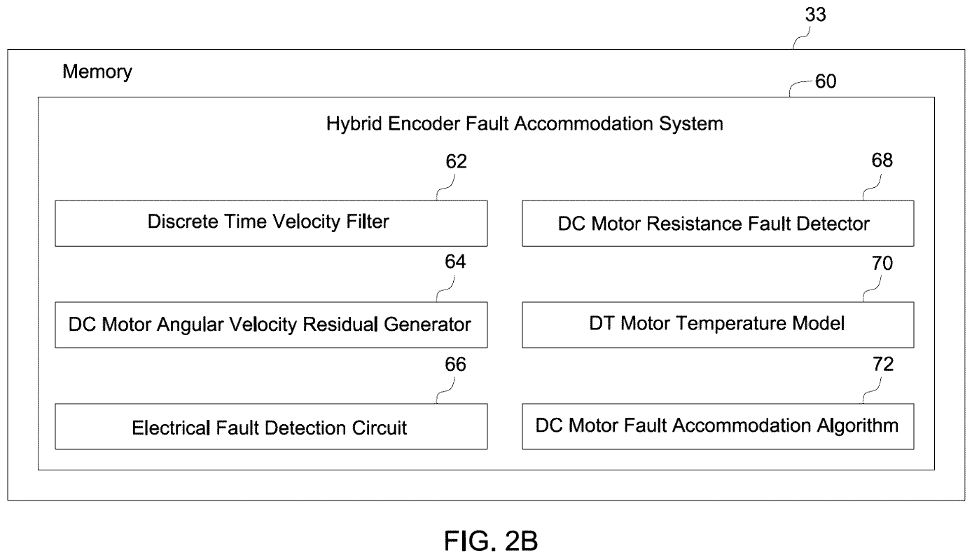

FIG. 1 is a side, perspective view of a treatment system according to at least one example embodiment. In at least one example embodiment, treatment system 10 may be used to perform catheter-based medical procedures, such as percutaneous intervention procedures including a percutaneous coronary intervention (PCI) (e.g., to treat STEMI), a neurovascular interventional procedure (NVI) (e.g., to treat an emergent large vessel occlusion (ELVO)), and/or peripheral vascular intervention procedures (PVI) (e.g., for critical limb ischemia (CLI), etc.). An example system includes that shown and described in U.S. Ser. No. 17/597,364 entitled, “MANIPULATION OF AN ELONGATED MEDICAL DEVICE” and U.S. Ser. No. 18/255,648 entitled, “SYSTEM AND APPARATUS FOR MANIPULATING AN ELONGATED MEDICAL DEVICE IN A ROBOTIC CATHETER-BASED PROCEDURE SYSTEM”; both applications being incorporated by reference herein, in their entirety. Catheter-based medical procedures may include diagnostic catheterization procedures during which one or more catheters or other elongated medical devices (EMDs) are used to aid in the diagnosis of a patient's disease. Catheter-based medical procedures may also include catheter-based therapeutic procedures (e.g., angioplasty, stent placement, treatment of peripheral vascular disease, clot removal, arterial venous malformation therapy, treatment of aneurysm, etc.) during which a catheter (or other EMD) is used to treat a disease. Therapeutic procedures may be enhanced by the inclusion of adjunct devices 54 (shown in FIG. 2A) such as, intravascular ultrasound (IVUS), optical coherence tomography (OCT), fractional flow reserve (FFR), etc. In at least one example embodiment, percutaneous intervention devices or components (e.g., type of guidewire, type of catheter, etc.) may be selected based on the type of procedure that is to be performed.

In at least one example embodiment, a treatment system 10 includes a bedside unit 20 and at least one control station. The control station may include one or more of a local control station or a remote control station, such as a local control station 38 and/or a remote-control station 42 shown in FIG. 2A. Bedside unit 20 includes a robotic drive 24 and a positioning system 22 adjacent a patient 12. The patient 12 may be supported on a patient table 18. A first end of the positioning system 22 may be attached to an end of the patient table 18, as shown in FIG. 1. In other example embodiments, the first end of the positioning system 22 may be attached to a base or a cart, for example. In at least one example embodiment, the positioning system 22 is used to position and support the robotic drive 24. A second end of the positioning system 22 may be attached to the robotic drive 24. The positioning system 22 may comprise a robotic arm, an articulated arm, a holder, etc. The positioning system 22 and/or the robotic drive 24 may be moved out of the way to allow for the patient 12 to be placed on the patient table 18. Once the patient 12 is positioned on the patient table 18, the positioning system 22 may be used to situate or position the robotic drive 24 relative to the patient 12 for a procedure or treatment. In at least one example embodiment, the patient table 18 may be supported by a pedestal 17, which may be secured to a floor of a room. The patient table 18 is configured to move with multiple degrees of freedom, for example, roll, pitch, and yaw, relative to the pedestal 17. In at least one example embodiment, the bedside unit 20 may include controls and displays 46, as shown in FIG. 2A. For example, the controls and displays 46 may be located on a housing of the robotic drive 24 in some example embodiments.

In at least one example embodiment, the robotic drive 24 may be equipped with one or more devices and accessories 48, as shown in FIG. 2A. For example, the devices and accessories 48 may include one or more of guidewires, various types of catheters including but not limited to balloon catheters, stent delivery systems, stent retrievers, embolization coils, liquid embolics, aspiration pumps, device to deliver contrast media, medicine, hemostasis valve adapters, syringes, stopcocks, inflation device, etc. The one or more devices and accessories 48 may allow a user or operator to perform a procedure or treatment, such as a catheter-based medical procedure. In at least one example embodiment, the one or more devices and accessories 48 may include one or more motors 49. The one or more motors 49 may rotate elongated medical devices (EMDs) such as catheters, guidewires, microwires, and stents. The one or more motors 49 may drive EMDs linearly; e.g., distally (toward patient) or proximally (away from patient). The one or more motors 49 may drive the robotic arm, which supports the robotic drive. In at least one example embodiment, the one or more motors 49 may be those described in U.S. Ser. No. 18/045,842, entitled, “DRIVETRAIN FOR ELONGATED MEDICAL DEVICE,” the entirety of which is incorporated by reference herein and/or those described in U.S. Ser. No. 17/597,364, entitled, “MANIPULATION OF AN ELONGATED MEDICAL DEVICE,” the entirety of which is incorporated by reference herein.

In at least one example embodiment, the bedside unit 20 and/or the robotic drive 24 may include any number and/or combination of components to provide the bedside unit 20 with the functionality described herein. For example, the robotic drive 24 includes one or more device modules, such as a plurality of device modules 32a-d, mounted to a rail or linear member of the robotic drive 24. Each of the device modules 32a-d may be used to drive an EMD, such as a catheter or guidewire. For example, the robotic drive 24 may be used to automatically feed a guidewire into a diagnostic catheter and into a guide catheter in an artery of the patient 12. One or more devices, such as an EMD, may enter the body (e.g., a vessel) of the patient 12 at an insertion point 16 via, for example, an introducer sheath. Each of the device modules 32a-d include a drive module and cassette removably attached to the drive module. Each drive module is configured to move along a longitudinal axis of the robotic drive 24 with a bracket or stage.

In at least one example embodiment, the bedside unit 20 is in communication with the control station, allowing signals generated by the user inputs of the control station to be transmitted wirelessly or via hardwire to the bedside unit 20 to control various functions of bedside unit 20. For example, as shown in FIG. 2A, the control computing system 34 may be coupled between the bedside unit 20 and the local control station 38 and/or the remote-control station 42. The bedside unit 20 may also provide feedback signals (e.g., loads, speeds, operating conditions, warning signals, error codes, etc.) to the control computing system 34. Communication between the control computing system 34 and various components of the treatment system 10 may be provided via a communication link that may be a wireless connection, cable connections, or any other means or mechanism capable of allowing communication to occur between components.

In at least one example embodiment, the control station may be located at a local site (e.g., the local control station 38 as shown in FIG. 2A) or at a remote site (e.g., the remote-control station 42 shown in FIG. 2A). For example, the treatment system 10 may be operated by the local control station 38, the remote-control station 42, or both the local control station 38 and the remote-control station 42. At the local site, a user or operator and the local control station 38 are located in the same room or an adjacent room to the patient 12 and bedside unit 20. For example, a local site is the location of the bedside unit 20 and a patient 12 or subject (e.g., animal or cadaver). At the remote site, the user or operator uses the remote-control station 42 to control the bedside unit 20 remotely. For example, the remote site does not have physical access to the bedside unit 20 and/or patient 12. The remote-control station 42 may be configured to communicate with the bedside unit 20 and/or the control computing system 34 at the local site using communication systems and services 36 (shown in FIG. 2A), for example, through the Internet, a local area network (LAN), a wide area network (WAN), or another network.

In at least one example embodiment, the control station generally includes one or more input modules 28 configured to receive user inputs to operate various components or systems of treatment system 10. For example, the input modules 28 may be configured to cause the bedside unit 20 to perform various tasks using percutaneous intervention devices (e.g., EMDs) interfaced with the robotic drive 24 (e.g., to advance, retract, or rotate a guidewire, advance, retract or rotate a catheter, inflate or deflate a balloon located on a catheter, position and/or deploy a stent, position and/or deploy a stent retriever, position and/or deploy a coil, inject contrast media into a catheter, inject liquid embolics into a catheter, inject medicine or saline into a catheter, aspirate on a catheter, or to perform any other function that may be performed as part of a catheter-based medical procedure). The robotic drive 24 includes various drive mechanisms to cause movement (e.g., axial and/or rotational movement) of the components of the bedside unit 20 including the one or more devices and accessories 48.

In at least one example embodiment, the input modules 28 may include one or more touch screens, joysticks, scroll wheels, and/or buttons. An example of an input system that may be used with the present invention is described in U.S. Ser. No. 17/812,733, entitled, “Systems and methods for a control station for robotic interventional procedures using a plurality of elongated medical devices,” the entirety of which is incorporated by reference herein. In addition to input modules 28, the control station may use additional user controls 44, such as foot switches and microphones for voice commands, etc. The input modules 28 may be configured to advance, retract, or rotate various components and the one or more devices and accessories 48 such as, for example, a guidewire, and one or more catheters or microcatheters. Buttons may include, for example, an emergency stop button, a multiplier button, device selection buttons and automated move buttons. When an emergency stop button is pushed, the power (e.g., electrical power) is shut off or removed to bedside unit 20. When in a speed control mode, a multiplier button acts to increase or decrease the speed at which the associated component is moved in response to a manipulation of input modules 28. When in a position control mode, a multiplier button changes the mapping between input distance and the output commanded distance. Device selection buttons allow the user or operator to select which of the percutaneous intervention devices loaded into the robotic drive 24 are controlled by input modules 28. Automated move buttons are used to enable algorithmic movements that the treatment system 10 may perform on a percutaneous intervention device without direct command from the user or operator. In one embodiment, input modules 28 may include one or more controls or icons (not shown) displayed on a touch screen (that may or may not be part of a display), that, when activated, cause operation of a component of the treatment system 10. Input modules 28 may also include a balloon or stent control that is configured to inflate or deflate a balloon and/or deploy a stent. Each of the input modules 28 may include one or more buttons, scroll wheels, joysticks, touch screen, etc. that may be used to control the particular component or components to which the control is dedicated. In addition, one or more touch screens may display one or more icons (not shown) related to various portions of input modules 28 or to various components of treatment system 10.

In at least one example embodiment, the treatment system 10 includes an imaging system 14. For example, the imaging system 14 may include one or more of a non-digital X-ray, a digital X-ray, Computed Tomography (CT), Magnetic Resonance Imaging (MRI), ultrasound, etc. In at least one example embodiment, the imaging system 14 includes a digital X-ray imaging device in communication with the control station. In at least one example embodiment, the imaging system 14 may include a C-arm that allows imaging system 14 to partially or completely rotate around patient 12 in order to obtain images at different angular positions relative to patient 12 (e.g., sagittal views, caudal views, anterior-posterior views, etc.). In at least one example embodiment, the imaging system 14 may be a fluoroscopy system including a C-arm having an X-ray source 13 and a detector 15, also known as an image intensifier.

In at least one example embodiment, the imaging system 14 may be configured to take X-ray images of a desired area of the patient 12 during a procedure. For example, the imaging system 14 may be configured to take one or more X-ray images of the head to diagnose a neurovascular condition. The imaging system 14 may also be configured to take one or more X-ray images (e.g., real time images) during a catheter-based medical procedure to assist the user or operator of the control station to properly position a guidewire, guide catheter, microcatheter, stent retriever, coil, stent, balloon, etc. during the procedure. The image or images may be displayed on a display 30. For example, images may be displayed on the display 30 to allow the user or operator to accurately move a guide catheter or guidewire into a proper or desired position.

In at least one example embodiment, the robotic drive 24 includes a housing having a top or first member 24a; a bottom or second member opposite and parallel to the first member 24a; a front or third member 24c substantially perpendicular and extending between the first member 24a and the second member, and a fourth member opposite and parallel to the third member 24c and perpendicular to first member 24a and the second member. The third member 24c may be configured to face the user when the robotic drive 24 is in use. In at least one example embodiment, the robotic drive 24 includes a distal region 24e and a proximal region 24f opposite the distal region 24e.

FIG. 2A is a block diagram of the treatment system of FIG. 1 according to at least one example embodiment. In at least one example embodiment, the control computing system 34 may be part of the control station, such as the local control station 38 and/or the remote-control station 42. The control computing system 34 may generally be an electronic control unit configured to provide the treatment system 10 with the various functionalities described herein. For example, the control computing system 34 may be an embedded system, a dedicated circuit, a general-purpose system programmed with the functionality described herein, etc. The control computing system 34 may be in communication with the bedside unit 20, the communications systems and services 36 (e.g., through Internet, firewalls, cloud services, session managers, a hospital network, etc.), the local control station 38, additional communications systems 40 (e.g., a telepresence system), the remote-control station 42, and patient sensors 56 (e.g., electrocardiogram (ECG) devices, electroencephalogram (EEG) devices, blood pressure monitors, temperature monitors, heart rate monitors, respiratory monitors, etc.). The control computing system 34 may also be in communication with the imaging system 14, the patient table 18, additional medical systems 50, contrast injection systems 52, and adjunct devices 54 (e.g., IVUS, OCT, FFR, etc.).

The control computing system 34 may include at least one memory 33 and at least one processor 35. The at least one memory 33 may include various special purpose program codes including computer executable instructions which may cause the at least one processor 35 of the control computing system 34 to perform one or more of the methods according to example embodiments described herein.

In at least one example embodiment, the control computing system 34 is configured to generate control signals based on the user's interaction with input modules 28 (e.g., of a control station such as a local control station 38 or a remote-control station 42) and/or based on information accessible to control computing system 34 such that a medical procedure may be performed using the treatment system 10. For example, the control computing system 34 may be in communication with the bedside unit 20, the robotic drive 24, the positioning system 22, and the additional controls and displays 46 and may provide control signals to one or more of the bedside unit 20, the robotic drive 24, the positioning system 22, and additional controls and displays 46 to control the operation of the motors and drive mechanisms used to drive the percutaneous intervention devices (e.g., guidewire, catheter, etc.). For example, the various drive mechanisms may be part of the robotic drive 24. In at least one example embodiment, the control computing system 34 may be in communication with the robotic drive 24 over etherCAT such that the control computer system 34 may implement fault detection, accommodation, and control processes described herein. Information related to the fault detection, accommodation, and control processes may be communicated from the robotic drive 24 back to the control computing system 34 to allow the control computing system 34 to respond to detected faults by at least one of communicating with an operator or determining a supervisory control decision. The local control station 38 may include one or more displays 30, one or more input modules 28, and the additional user controls 44.

The remote-control station 42 and the control computing system 34 may include similar or analogous components as the local control station 38. The remote-control station 42 and the local control station 38 may be different and tailored based on their required functionalities. In at least one example embodiment, the additional user controls 44 include one or more foot input controls. The foot input controls may be configured to allow the user to select functions of the imaging system 14, such as turning on and off the X-ray and scrolling through different stored images. In another example embodiment, the foot input controls may be configured to allow the user to select which devices are mapped to scroll wheels included in input modules 28. In at least one example embodiment, additional communication systems 40, such as audio and/or video communications, may be employed to help the operator interact with the patient, medical staff, and/or equipment in the vicinity of the bedside.

FIG. 2B is a block diagram of the memory 33 of the control computing system 34 of FIG. 2A. The memory 33 may store one or more programs that form a hybrid encoder fault accommodation system 60. The hybrid encoder fault accommodation system 60 may enable motor control and may ensure that the percutaneous intervention devices described above operate in a fail-safe manner. In at least one example embodiment, the fault accommodation systems described herein may allow robotic platforms such as the percutaneous intervention devices described above to complete large vessel thrombectomy interventions in a fail-safe manner. In at least one example embodiment, the hybrid encoder fault accommodation system 60 for motor control may be implemented via the control computing system 34 for the motor 49 of the treatment system 10. In particular, the functions described herein may be executed by the at least one processor 35 of the control computing system 34 in at least one example embodiment.

The hybrid encoder fault accommodation system 60 includes a discrete time velocity filter 62, a DC motor angular velocity residual generator 64, an electrical fault detection circuit 66, a DC motor resistance fault detector 68, a discrete time (“DT”) motor temperature model 70, and a DC motor fault accommodation algorithm 72. In at least one example embodiment, each of the discrete time velocity filter 62, the DC motor angular velocity residual generator 64, the electrical fault detection circuit 66, the DC motor resistance fault detector 68, the DT motor temperature model 70, and the DC motor fault accommodation algorithm 72 may be models stored in the memory 33 of the control computing system 34. The hybrid encoder fault accommodation system 60 as applied to the motor 39 may be configured to determine an estimated angular velocity of the motor and an estimated angular position of the motor, detect a sensor fault of a motor encoder of the motor, and in response to detecting the sensor fault, detect at least one additional fault using at least one of the estimated angular velocity or the estimated angular position.

In at least one example embodiment, the discrete time velocity filter 62 may be configured to maintain both passivity and stability of a continuous time velocity filter. In particular, the discrete time velocity filter 62 may enable minimal impact on a closed-loop stability of a motor control system while eliminating the need for an additional tachometer sensor to measure an angular velocity of the motor. The discrete time velocity filter 62 has a z-transform of:

$$\frac{{ω}_{f} ( z )}{θ ( z )} = \frac{{ω}_{b}}{s + {ω}_{b}} \vert s = \frac{2 ( 1 - {z}^{- 1} )}{T s ( 1 + {z}^{- 1} )}$$

where ω_{f}(z) is a sensed angular velocity of the motor, θ(z) is a sensed angular position of the motor, ω_{b} is a positive real number less than or equal to the Nyquist frequency

$$\frac{π}{T s} ,$$

and Ts is the discrete sampling time.

In at least one example embodiment, the estimated angular velocity may be determined in more than one way. For example, a first estimated angular velocity may be determined based on an estimated coil resistance of the motor, a measured motor voltage, a measured motor current, a filtered motor current, and an inductance. The estimated coil resistance of the motor may be referred to herein as an estimated motor coil resistance. A second estimated angular velocity may be determined based on a measured current and a model of a motor plant in response to an electrical fault being detected.

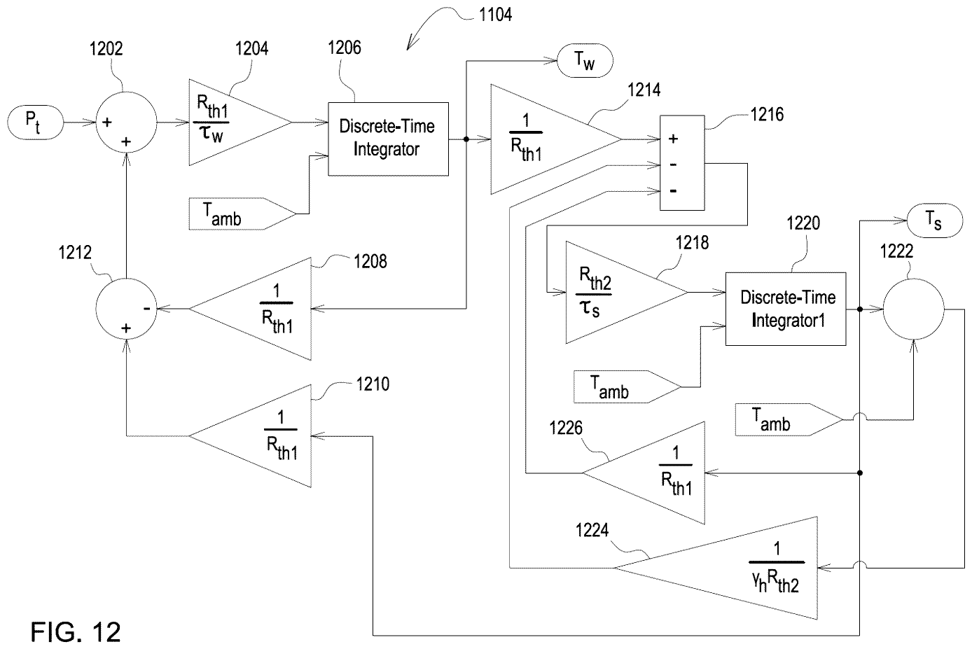

In particular, the first estimated angular velocity, ωᵥ[k], may be determined by

$${ω}_{v} [ k ] = \frac{1}{{k}_{t}} ( ( v [ k - 1 ] - {R}_{T} i [ k - 1 ] - {Li}_{f} [ k ] )$$

where k is a time index of the DT domain, kₜ is greater than zero and is a motor torque constant, R_{T} is a motor resistance, v[k] is a measured motor voltage, i[k] is a measured motor current, i_{f}[k] is the time derivative of a filtered motor current, and L is the inductance. The motor resistance, R_{T} may be determined from an estimated motor coil temperature, T_{W}, such that R_{T}=R(T_{W}). The estimated motor coil temperature is described in additional detail below in FIG. 12. The product of the inductance multiplied by the time derivative of the filtered motor current, Li_{f}[k], may be determined by Li_{f}[k]=Lω_{d}[k](i[k]−i_{f}[k]) where the filtered motor current i_{f}[k] is computed from a DT positive real filter:

$$\frac{{i}_{f} ( z )}{i ( z )} = \frac{{ω}_{d}}{s + {ω}_{d}} \vert s = \frac{2 ( 1 - {z}^{- 1} )}{T s ( 1 + {z}^{- 1} )}$$

where i(z) is the measured motor current, ω_{d} is a positive real number that determines a bandwidth of the filter in radians/second, and Ts the discrete sampling time in seconds (s). In at least one example embodiment, ω_{d} may be a DT sampling Nyquist frequency such as

$$\frac{π}{{T}_{s}} .$$

In at least one example embodiment, the first estimated angular velocity is saturated at ±2ωₘₐₓ where ωₘₐₓ is a no load angular velocity rating of the motor.

An estimated angular position of the motor may be the integral of the first estimated angular velocity such that

$$\frac{{θ}_{v} ( z )}{{ω}_{v} ( z )} = \frac{Ts ( 1 + {z}^{- 1} )}{2 ( 1 - {z}^{- 1} )} .$$

The estimated angular position, θᵥ, may have a maximum value, θₘₐₓ. When the estimated angular position, θᵥ, reaches ±θₘₐₓ the estimated angular position may be reset to zero.

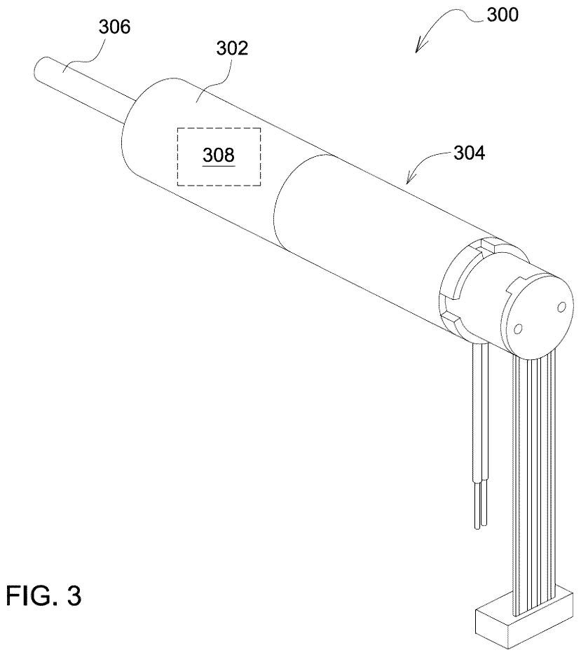

FIG. 3 shows a motor assembly 300. The motor assembly 300 may include a gearbox 302, a motor 304, an output shaft 306, and an encoder 307. The gearbox 302 may be coupled between the motor 304 and the output shaft 306. The encoder 307 may be coupled to the motor 304 opposite the gearbox 302. In at least one example embodiment, the motor assembly 300 may include one or more sensors 308. The one or more sensors 308 may be configured to sense an angular velocity and angular position of the motor of the motor assembly 300.

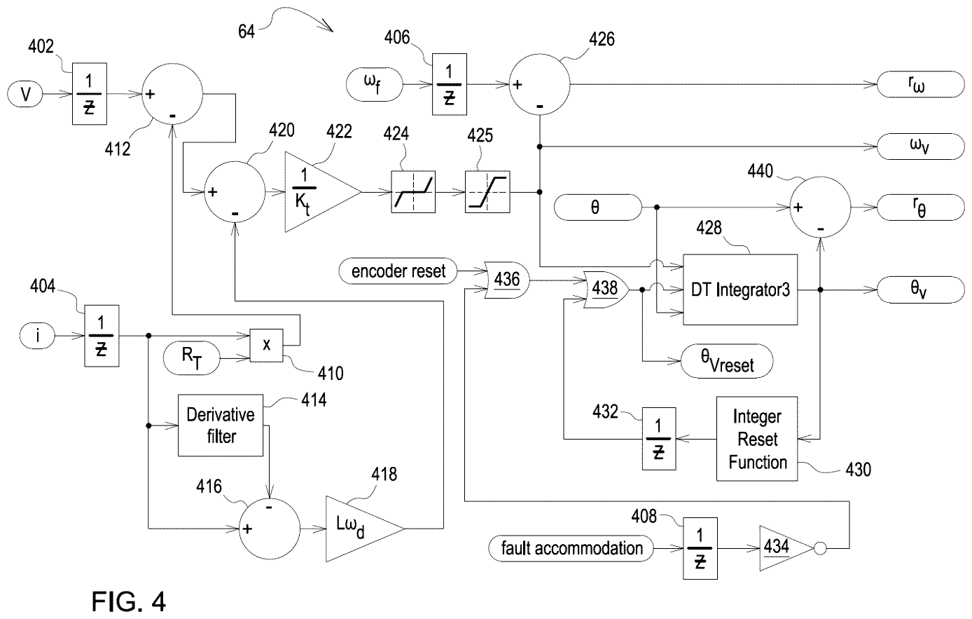

As shown in FIG. 4, the DC motor angular velocity residual generator 64 may be used to determine a residual of the first estimated angular velocity, r_{ω}, and a residual of the estimated angular position, r_{θ}. The residual of the first estimated angular velocity, r_{ω}, may be determined based on a sensed angular velocity of the motor and the first estimated angular velocity of the motor. In particular, the residual of the first estimated angular velocity, r_{ω}, may be determined by r_{ω}[k]=ω_{f}[k]−ωᵥ[k] where ωᵥ[k] is the first estimated angular velocity described above and ω_{f}[k] is a sensed angular velocity of the motor. The residual of the estimated angular position, r_{θ}, may be determined based on a sensed angular position of the motor and the estimated angular position of the motor. The sensed angular position of the motor encoder may be sensed by one or more sensors of the motor encoder. The residual of the estimated angular position, r_{θ}, may be determined by r_{θ}[k]=θ[k]−θᵥ[k] where θᵥ[k] is the estimated angular position described above and θ[k] is a sensed angular position of the motor. In at least one example embodiment, a motor encoder may be used to sense the sensed angular velocity of the motor and the sensed angular position of the motor. The motor encoder may include at least one sensor that may be used to sense the sensed angular velocity of the motor and the sensed angular position of the motor.

In further detail, the angular velocity residual generator 64 may include seven inputs, the measured motor voltage, v[k], the measured motor current, i[k], the sensed angular position of the motor, θ[k], an encoder reset input, and the sensed angular velocity of the motor, ω_{f}[k], a fault accommodation input, and the motor resistance, R_{T}. At block 402 the measured motor voltage, v[k], is input into a unit delay block which outputs the measured motor voltage at k−1, v[k−1]. Similarly, at block 404 the measured motor current, i[k], is input into a unit delay block which outputs the measured motor current at k−1, i[k−1], at block 406 the sensed angular velocity of the motor, ω_{f}[k], is input into a unit delay block which outputs the sensed angular velocity at k−1, ω_{f}[k−1], and at block 408 the fault accommodation input is input into a unit delay block which outputs a fault accommodation at k−1.

At block 410, the motor resistance, R_{T} is multiplied by the output of block 404: R_{T}i[k−1]. At block 412, R_{T}i[k−1] is subtracted from the output of block 402: v[k−1]−R_{T}i[k−1].

At block 414, a derivative filter is used to determine the time derivative of the filtered motor current, i_{f}[k]. The derivative filter may be the DT positive real filter described above:

$$\frac{{i}_{f} ( z )}{i ( z )} = \frac{{ω}_{d}}{s + {ω}_{d}} \vert s = \frac{2 ( 1 - {z}^{- 1} )}{T s ( 1 + {z}^{- 1} )} .$$

At block 416, the filtered motor current, i_{f}[k] is subtracted from the output of block 404: i[k−1]−i_{f}[k]. At block 418, the product of the inductance multiplied by the time derivative of the filtered motor current, Li_{f}[k] is determined by multiplying the product of the inductance and the positive real number ω_{d} by i[k−1]−i_{f}[k]: Li_{f}[k]=Lω_{d}[k](i[k−1]−i_{f}[k]).

At block 420, the product of the inductance multiplied by the time derivative of the filtered motor current, Li_{f}[k] is subtracted from the output of block 412: v[k−1]−R_{T}i[k−1]−Li_{f}[k].

At block 422, v[k−1]−R_{T} i[k−1]−Li_{f}[k] is multiplied by the inverse of the torque constant

$$\frac{1}{{k}_{t}}$$

to output a first estimated angular velocity, ωᵥ₋ₒ[k]:

$${ω}_{v - 0} [ k ] = \frac{1}{{k}_{t}} ( ( v [ k - 1 ] - {R}_{T} i [ k - 1 ] - {Li}_{f} [ k ] ) .$$

Block 424 is a dead-band block which the first estimated angular velocity, ωᵥ₋ₒ[k], is passed through and outputs a first estimated angular velocity: ω_{v-d}[k]=dead(ωᵥ₋ₒ[k], −ω_{dead},ω_{dead}). In which:

$${ω}_{v - d} [ k ] = \{ \begin{matrix}{ω}_{v - o} [ k ] + {ω}_{dead} , if {ω}_{v - o} [ k ] < - {ω}_{dead} \\ 0 , if - {ω}_{dead} \leq {ω}_{v - o} [ k ] \leq {ω}_{dead} \\ {ω}_{v - o} [ k ] - {ω}_{dead} , if {ω}_{v - o} [ k ] > {ω}_{dead}\end{matrix}$$

Block 425 is a saturation block where the first estimated angular velocity is passed through to output the first estimated angular velocity ωᵥ[k]: ωᵥ[k]=sat(ω_{v-d}[k], −2ωₘₐₓ, 2ωₘₐₓ). In which

$${ω}_{v} [ k ] = \{ \begin{matrix}- 2 {ω}_{max} , if {ω}_{v - d} [ k ] < - 2 {ω}_{max} \\ {ω}_{v - d} [ k ] , if - 2 {ω}_{max} \leq {ω}_{v - o} [ k ] \leq 2 {ω}_{max} \\ 2 {ω}_{max} , if {ω}_{v - d} [ k ] < 2 {ω}_{max}\end{matrix}$$

At block 426, the first estimated angular velocity, ωᵥ[k], is subtracted from the sensed angular velocity of the motor, ω_{f}[k]: ω_{f}[k]−ωᵥ[k]. The output of block 426 is the residual of the first estimated angular velocity, r_{ω} as described above.

At block 428 an integral of the first estimated angular velocity, ωᵥ[k], is determined as the estimated angular position of the motor, θᵥ[k], such that

$$\frac{{θ}_{v} ( z )}{{ω}_{v} ( z )} = \frac{Ts ( 1 + {z}^{- 1} )}{2 ( 1 - {z}^{- 1} )}$$

as described above.

Further, as described above, when the estimated angular position, θᵥ[k], reaches ±θₘₐₓ the estimated angular position may be reset to zero. At block 430, the estimated angular position, θᵥ[k], is input into an integer reset function so that its corresponding integrator reset output, y_{θ-reset}[k], is true if |θᵥ[k]|≥θₘₐₓ otherwise it is false. At block 432, the output of block 430 is input into a unit delay block whose corresponding output is y₀₋ᵣₑₛₑₜ[k−1]. At block 434, the Boolean output of block 408, u_{fault accommodation}[k−1], is the logical NOT of its input such that ¬u_{fault accommodation}[k−1] is the result. Then, at block 436, the output of block 434 and the encoder reset input are input into an AND function. If both inputs to the and function are true, then the output is true, else, the output is false. Then, at block 438, the output of block 436 and the output of block 432 are input into an or block. If either the output of block 436 or the output of block 432 are true, then the estimated angular position, θᵥ[k], is reset to zero.

Finally, at block 440, the estimated angular position, θᵥ[k], is subtracted from the sensed angular position of the motor, θ[k]: θ[k]−θᵥ[k]. This result of block 440 is the residual of the estimated angular position, r_{θ}.

The motor encoder may be an encoder as is known in the art. Thus, the motor encoder may have a first pin, a second pin, and an index pin. Motor encoder faults may be determined based on the outputs of the first pin, the second pin, and the index pin. The motor encoder faults may be a sensor fault of the motor encoder. The outputs of the pins of the motor encoder may be either high or low. An invalid state of the motor encoder may be detected when an output of the first pin or the second pin is low and an output of the index pin is high.

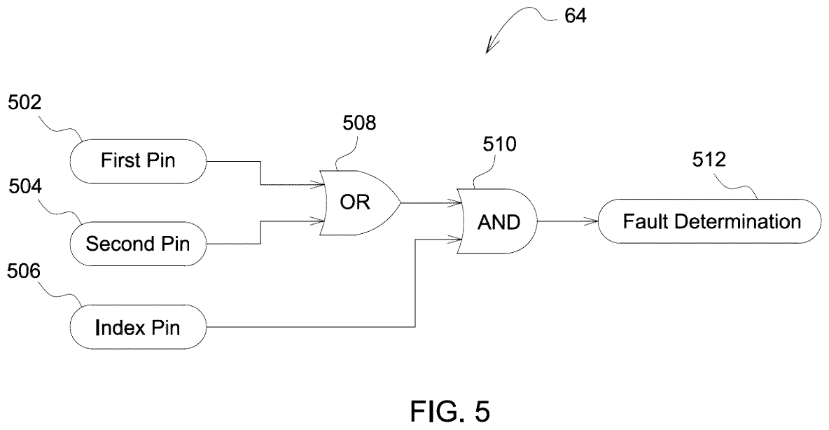

FIG. 5 is a diagram of the electrical fault detection circuit 66. The electrical fault detection circuit 66 may be configured to detect a motor encoder fault as described above. In particular, an output of the first pin 502, and output of the second pin 504, and an output of the index pin 506 may be analyzed to determine whether there is a fault within the motor encoder. The output of the first pin 502 and the output of the second pin 504 may be analyzed at block 508 to determine if either the output of the first pin 502 or the output of the second pin 504 is high. If so, then the output of the index pin 506 is analyzed at block 510. If the output of the index pin 506 is high and either the output of the first pin 502 or the output of the second pin 504 is high, then a fault is detected in the motor encoder at step 512. If either the or block 508 or the and block 510 is not satisfied, then there is not a motor encoder fault detected by the diagram 500.

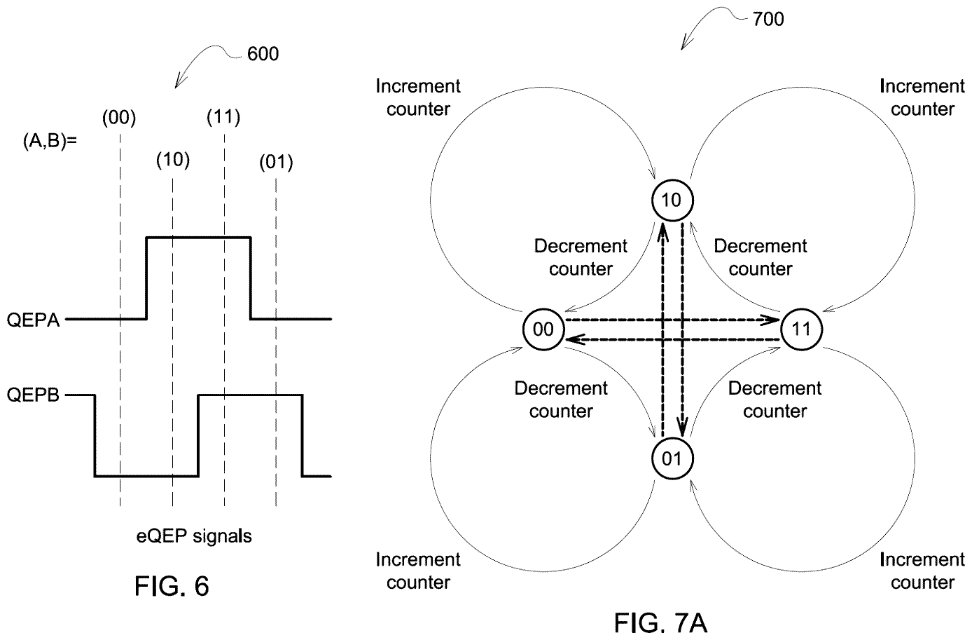

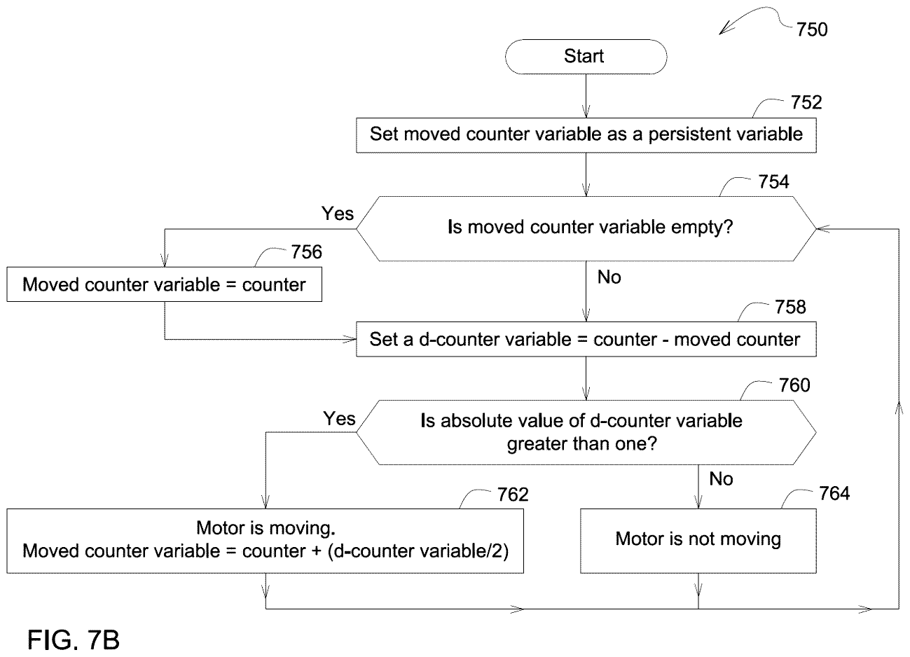

FIG. 6 is a diagram 600 of an output of a first pin and a second pin of a motor encoder. The first pin of the diagram of FIG. 6 may be the first pin 502 denoted as QEPA and the second pin may be the second pin 504 denoted as QEPB. As described above, an encoder shall never have an output of the first pin 502 or QEPA be true while the index pin 506 is true. Similarly, an output of the second pin 504 or QEPB is not true if the index pin 506 is true. FIG. 7A is a state diagram 700 of decoding a quadrature encoder to increment or decrement a counter. As shown in the diagram 600, when (A,B)=(0,0) the output of both the first pin and the second pin is low. When (A,B)=(1,0) the output of the first pin is high and the output of the second pin is low. When (A,B)=(1,1) the output of the first pin and the second pin is high. When (A,B)=(0,1) the output of the first pin is low and the output of the second pin is high.

Referring to FIG. 7A, the state diagram 700 shows how to increment or decrement a counter depending on the state of the first pin and the second pin. When the index pin is still functioning, a fault may occur if the output of the first pin is always high, the output of the second pin is always high, or both the output of the first pin and the output of the second pin are always high. If the first pin is always high, the counter may start at zero when (A,B)=(1,0). As the output of the second pin changes to (A,B)=(1, 1), the counter will increase by one. Then, the output of the first pin and the second pin will change to (A,B)=(1,0) which will decrease the counter by one. Thus, the counter is changing from one to zero but is only changing by one each time a state of one of the pins is changed. Similarly, if the second pin is always high, the counter may start at zero when (A,B)=(0,1). As the output of the first pin changes to (A,B)=(1, 1), the counter will decrease by one. Then, the output of the first pin and the second pin will change to (A,B)=(0,1) which will increase the counter by one. Thus, the counter is similarly changed by one each time. If both the output of first pin and the second pin are high, (A,B)=(1,1) there is no change. Thus the counter is neither increased nor decreased because the output of the first pin and the second pin is unchanged.

In order to detect any of the three above-described faults of the motor encoder, an algorithm is needed to detect motion within the motor because the output of the motor encoder cannot be used to accurately detect motion within the motor.

FIG. 7B is a flow chart of an algorithm 750 for detecting motion within the motor. The algorithm 750 is described with reference to the processor 35 of FIG. 2. The method 750 begins by initiating a moved counter variable as a persistent variable at step 752. At conditional step 754 the processor determines if the moved counter variable is empty. If the moved counter variable is empty, then at step 756 the processor 35 sets the moved counter variable to equal the counter. If the moved counter variable is not empty or if the moved variable has been set to equal the counter at step 756, the processor 35 then sets a d-counter variable to equal the counter minus the moved counter variable at step 758. Then at conditional step 760, the processor 35 determines if the absolute value of the d-counter variable is greater than one. If the absolute value of the d-counter variable is greater than one, then the motor is moving and at step 762 the processor 35 updates the moved counter variable to equal the counter plus the d-counter variable divided by two: moved counter=counter+bitshift(d-counter, −1). If the absolute value of the d-counter variable is not greater than one, then the processor 35 determines that the motor is not moving at step 764. From step 762 and step 764, the algorithm returns to conditional step 754 where the processor 35 re-executes steps 754-764 as described above.

If the output of the first pin and the second pin is moving along one of the dashed lines as shown in FIG. 7A, then there is a phase error within the system. This fault may be detected when a phase error flag is true. The phase error flag may be set if both the outputs of the first pin and the second pin change along a path of a dashed line in the diagram 700. In at least one example embodiment, the fault may be at least one of an open circuit or a short circuit.

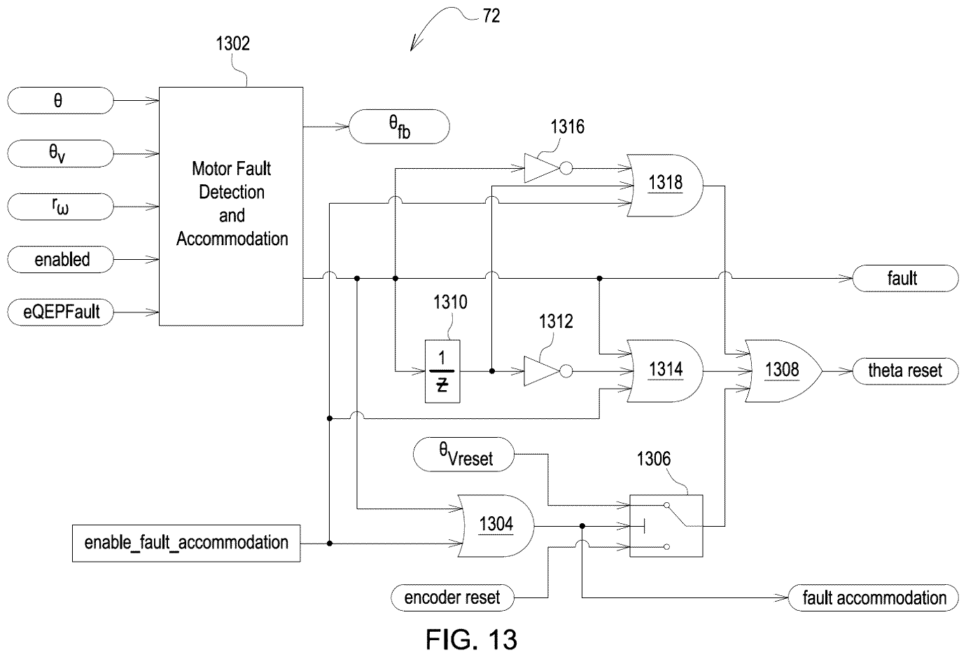

If the motor encoder fails by either the first pin being always high or the second pin being always high, the residual of the first estimated velocity or the residual of the estimated angular position may be used to detect the fault. Additional details of using the residual of the first estimated velocity or the residual of the estimated angular position are described below with reference to FIG. 13.

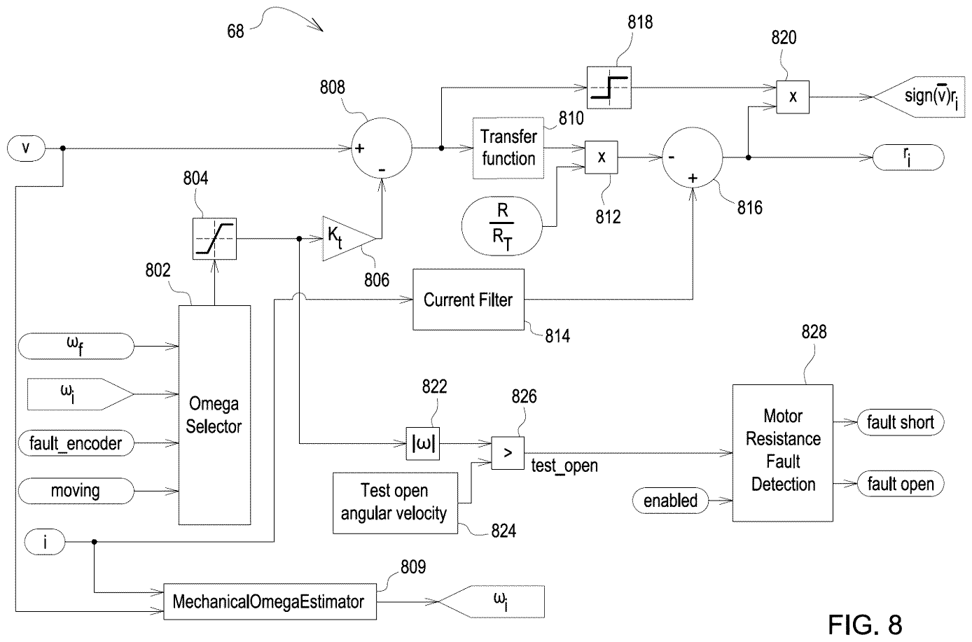

FIG. 8 is a diagram of the DC motor resistance fault detector 68. The DC motor resistance fault detector 68 may be used to determine if there is a motor encoder fault that is either a short circuit or an open circuit. In at least one example embodiment, an open circuit may be detected if a motor velocity is nearing zero.

The DC motor resistance fault detector 68 may include seven inputs: the measured motor current, i[k], the measured motor voltage, v[k], the sensed angular velocity of the motor, ω_{f}[k], an enabled condition input, a fault encoder input, a result of a motor winding resistance at room temperature, R, divided by a motor winding resistance at elevated temperature due to thermal heating from the current being applied to the motor, R_{T}:

$$\frac{R}{{R}_{T}} ,$$

and a Boolean moving condition input. In at least one example embodiment,

$$\frac{R}{{R}_{T}} = 1$$

when the motor has been off and not heated up.

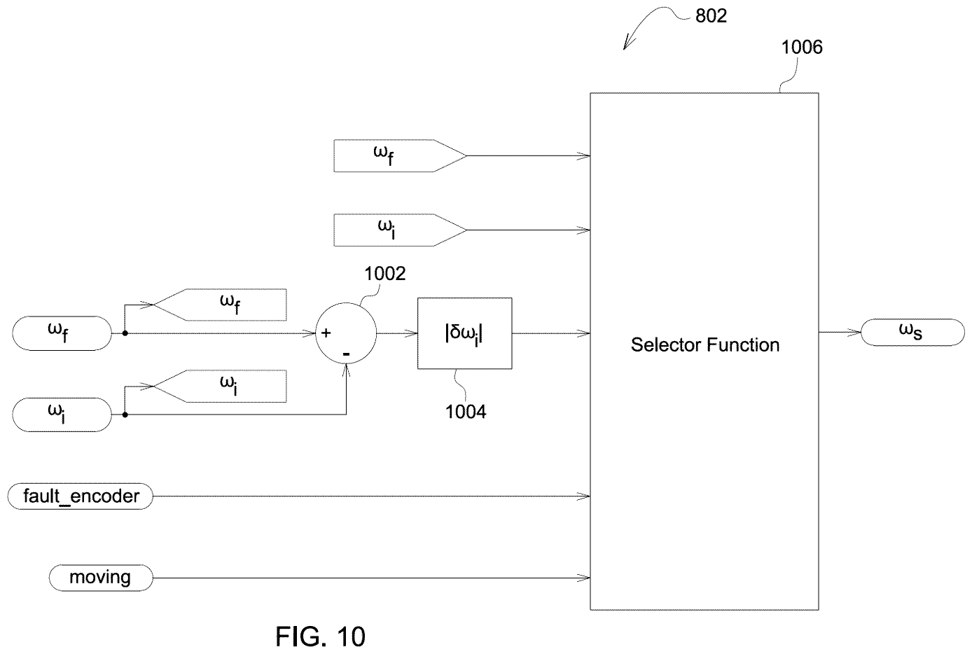

A fundamental relationship between the measured motor voltage, v(t), a motor resistance, R, a motor inductance, L, a current, i(t), and a selected angular velocity, ωₛ(t), exists such that: v̅(t)=v(t)−kₜωₛ(t)=(Ri(t)+Li(t)). At block 802, the sensed angular velocity of the motor, ω_{f}[k], the second estimated angular velocity, ωᵢ, the fault encoder input, and the moving condition input are input into an omega selector function. The omega selector function will return the selected angular velocity, ωₛ(t). Further details of the omega selector function are described below with respect to FIG. 10.

At block 804, the selected angular velocity, ωₛ(t) is input into a saturation block such that its output is ω_{select}[k]=sat(ωₛ[k], −2ωₘₐₓ, 2ωₘₐₓ) Such that:

$${ω}_{select} [ k ] = \{ \begin{matrix}- 2 {ω}_{max} , if {ω}_{s} [ k ] < - 2 {ω}_{max} \\ {ω}_{v - d} [ k ] , if - 2 {ω}_{max} \leq {ω}_{s} [ k ] \leq 2 {ω}_{max} \\ 2 {ω}_{maz} , if {ω}_{s} [ k ] < 2 {ω}_{max}\end{matrix}$$

Then, at block 806, the output of the saturation block is multiplied by the motor torque constant, kₜω_{select}[k]. Then, at block 808, the output of block 806 is subtracted from the measured motor voltage, v[k], resulting in the fundamental relationship described above: v̅(t)=v(t)−kₜωₛ(t).

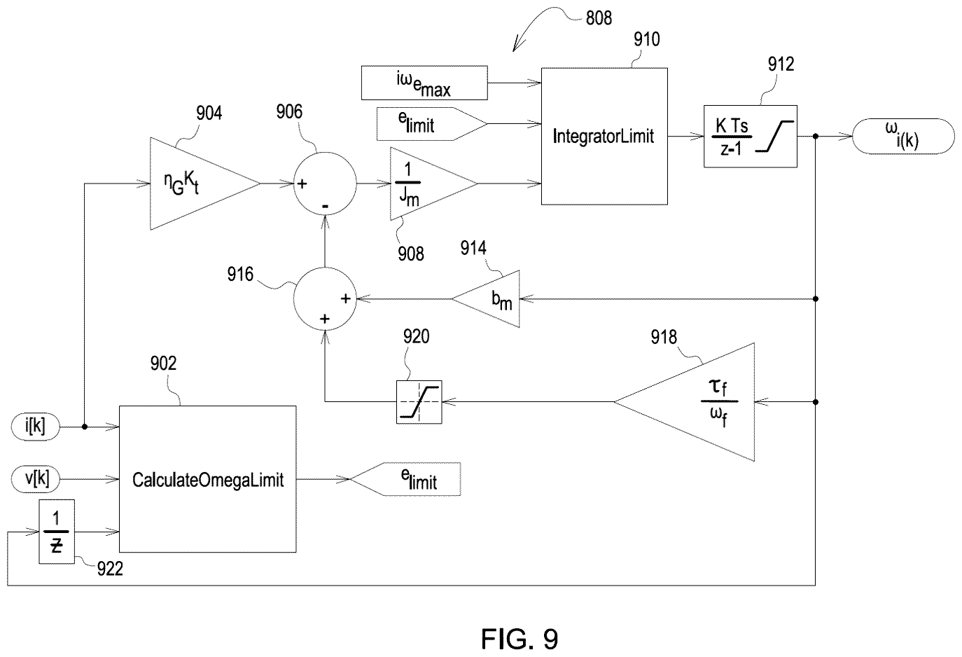

At block 809, the second estimated angular velocity, ωᵢ, is determined by a mechanical omega estimator function. The mechanical omega estimator function may take the measured motor current, i[k] and the measured motor voltage, v[k], as inputs. Further details of the mechanical omega estimator function are described below with respect to FIG. 9.

The DC motor resistance fault detector may also define a current estimator and a current filter. At block 810, the transfer function is

$$\frac{{Y}_{810} ( z )}{\overline{v} ( z )} = \frac{1}{( \frac{L}{{k}_{a}} ) s + R} \vert s = \frac{2 ( 1 - {z}^{- 1} )}{T s ( 1 + {z}^{- 1} )}$$

which after substitution of s results in the equivalent expression

$$\frac{{Y}_{810} ( z )}{\overline{v} ( z )} = \frac{1}{( \frac{L}{{k}_{a}} ) \frac{2 ( 1 - {z}^{- 1} )}{T s ( 1 + {z}^{- 1} )} + R} .$$

The output of block 812 is used to define a current estimator whose output is iᵥ[k]. The current estimators resulting transfer function may be:

$$\frac{{i}_{v} ( z )}{\overline{v} ( z )} = \frac{R}{{R}_{T}} \frac{1}{( \frac{L}{{k}_{a}} ) s + R} \vert s = \frac{2 ( 1 - {z}^{- 1} )}{T s ( 1 + {z}^{- 1} )} .$$

At block 812, the output of block 810 is multiplied by

$$\frac{R}{{R}_{T}}$$

to determine the estimated current, iᵥ[k]. The current filter discrete time transfer function may be:

$$\frac{{i}_{f} ( z )}{i ( z )} = \frac{{ω}_{n}}{s + {ω}_{n}} \vert s = \frac{2 ( 1 - {z}^{- 1} )}{T s ( 1 + {z}^{- 1} )}$$

which after substitution of s results in the equivalent expression:

$$\frac{{i}_{f} ( z )}{i ( z )} = \frac{{ω}_{n}}{\frac{2 ( 1 - {z}^{- 1} )}{T s ( 1 + {z}^{- 1} )} + {ω}_{n}} , where {ω}_{n} = \frac{π}{T s} and {k}_{a} = min ( \frac{L {ω}_{n}}{R} , 1 ) .$$

At block 814, the current filter may be used to determine the sensed current, i_{f}. At block 816, a current residual, rᵢ, may be determined by subtracting the estimated current from the sensed current: rᵢ=i_{f}−iᵥ.

At block 818, sign(v̅) is determined and at block 820, a product of sign(v̅) and the current residual, rᵢ which equals sign(v̅)rᵢ, is determined.

At block 822, the absolute value of the measured angular velocity is determined. At block 824, a percentage of a scaled down value of a maximum motor angular velocity. In at least one example embodiment, the maximum motor angular velocity may be multiplied by 0.05. 0.05 is a non-limiting example value used to scale down the maximum motor angular velocity. In at least one example embodiment, the maximum motor angular velocity may be scaled by a different value such as 0.25 or 0.1 as non-limiting examples. At block 826 the absolute value of the measured angular velocity is compared to the scaled down value of a maximum motor angular velocity. A test open condition is true when the absolute value of the measured angular velocity is less than a positively scaled down value of the motor max angular velocity.

At block 828, the test open condition, sign(v̅)rᵢ, and the enabled condition input are input into a motor resistance fault detection function. A short circuit may be detected if sign(v̅)rᵢ>r_{fault} and an open circuit may be detected if (|v|<0.1ωₘₐₓ)∧sign(v̅)rᵢ<−r_{fault} where r_{fault} is a constant positive real number that is used to set a threshold to detect either an open circuit or a short circuit while minimizing the rate of false positive detections of either an open circuit or a short circuit. In particular, a function may be defined to detect an open or a short circuit that includes at least a product of sign(v̅) and the current residual, rᵢ which equals sign(v̅)rᵢ, a test open condition, the discrete sampling time, Ts, t_{fault}, r_{fault}, and an enabled condition. In at least one example embodiment, the test open condition is true when the absolute value of the measured angular velocity is less than a positively scaled down value of the motor max angular velocity and the enabled condition is determined by the control computing system 34. The test open condition and the enabled condition are Boolean variables. For example, the test open condition may be true when

$$\vert ω \vert < \frac{{ω}_{max}}{4}$$

and may be false otherwise. The enabled condition may be true when the control computing system 34 is enabled and may be false otherwise.

The function may begin by defining persistent variables ko, ks, k_{fault}, in_fault_open, and in_fault_short, wherein ko is an open fault counter, ks is a short fault counter, k_{fault} is a persistent fault counter, in_fault_open is a true or false variable for detecting an open circuit fault, and in_fault_short is a true or false variable for detecting a short circuit fault. The function may then determine if the open fault counter, ko, is empty and if the enabled condition is enabled. If the open fault counter, ko, is empty and the enabled condition is not enabled, the function may define ko=int32(0), define ks=ko, define k_{fault}=int32(t_{fault}/Ts), define in_fault_open=false, and define in_fault_short=false.

The function may then determine whether to increment or decrement the short fault counter. In particular, if srᵢ>r_{fault}, the short fault counter is incremented by one: ks=ks+_int32(1). Otherwise, if the current residual is nearing zero and the motor does not include a short fault, the short fault counter is decreased by one. Thus, if (|srᵢ|<single(0.3)*r_{fault})&& (ks>int32(0))&& in_fault_short=false then ks=ks−int32(1).

The function may then determine whether to increment or decrement the open fault counter. The open fault counter may be incremented if the test open condition is true and srᵢ is sufficiently negative. Thus, if the test open function is true and srᵢ<−r_{fault} then ko=ko int32(1). Otherwise, if the current residual is nearing zero and the motor does not have an open short, the open fault counter is decreased by one. Thus, if (|srᵢ|<single (0.3)*r_{fault})&& (ko>int32(0))&& in_fault_open=false then ko=ko−int32(1).

Then, the function determines if an open circuit fault or a short circuit fault is detected. In particular, if (ko≥k_{fault}) && in_fault_open is not true, then in_fault_open is set to true. If (ks≥k_{fault}) && in_fault_short is not true, then in_fault_short is set to true. A short circuit fault is detected if the result of in_fault_short is true and an open circuit fault is detected if in_fault_open is true.

The DC motor resistance fault detector diagram 68 is designed to estimate an angular velocity of the motor based on the measured current and a physical model of the motor plant. This is the second estimated angular velocity described above. The second estimated angular velocity may be used if the motor encoder fails but still remains capable of detecting an electrical fault within the system.

FIG. 9 is the mechanical omega estimator 809 of FIG. 8. The mechanical omega estimator 809 may be used to determine the second estimated angular velocity, ωᵢ based, in part, on a physical model of the motor plant. The physical model of the motor plant may be a classic mechanical model that includes an estimated torque and a piece wise static friction component. The classic mechanical model may be:

$${J}_{total} {\dot{ω}}_{ι} [ k ] = - {b}_{m} {ω}_{i} [ k ] - sat ( \frac{{τ}_{f}}{{ω}_{friction}} {ω}_{i} [ k ] , - {τ}_{f} , {τ}_{f} ) + {η}_{G} {k}_{t} i [ k ]$$

where ±τ_{f} are the saturation limits of the static friction component and 0<η_{G}≤1 is a gear box efficiency.

The mechanical omega estimator 808 may begin at block 902 which is a function that takes the measured motor current, i[k], the measured motor voltage, v[k], and the second estimated angular velocity at [k−1], ωᵢ[k−1], as inputs and outputs an error term, eₗᵢₘᵢₜ, which is the expected steady state emf angular velocity,

$$\frac{v [ k ] - R i [ k ]}{{k}_{t}} ,$$

subtracted from the second estimated angular velocity, ωᵢ, in order to mitigate drift in the angular velocity measurement caused by unknown loads such as friction which is greater than the estimated friction. In order to address noise in low voltage and current sense measurements eₗᵢₘᵢₜ[k] can also be computed as follows:

$${e}_{limit} [ k ] = \{ \begin{matrix}{ω}_{i} [ k - 1 ] - \frac{v [ k ] - Ri [ k ]}{{k}_{t}} , if sign ( v [ k ] ) = sign ( v [ k ] - Ri [ k ] ) \\ {ω}_{i} [ k - 1 ] - \frac{v [ k ]}{{k}_{t}} , otherwise .\end{matrix}$$

At block 904, the measured motor current, i[k], is multiplied by η_{G}kₜ resulting in: η_{G}kₜi[k]. Then, at block 906, η_{G}kₜi[k] is added to the negative of the output of block 916. The output of block 916 is:

$$- {b}_{m} {ω}_{i} [ k ] - sat ( \frac{{τ}_{f}}{{ω}_{friction}} {ω}_{i} [ k ] , - {τ}_{f} , {τ}_{f} )$$

where =−bₘωᵢ[k] is an output of block 914 and

$$\frac{{τ}_{f}}{{ω}_{friction}} {ω}_{i} [ k ]$$

is an output of block 918 resulting in

$$- sat ( \frac{{τ}_{f}}{{ω}_{friction}} {ω}_{i} [ k ] , - {τ}_{f} , {τ}_{f} )$$

being an output of block 920.

At block 908, the output of block 906 is multiplied by

$$\frac{1}{{J}_{m}}$$

resulting in

$${ω}_{ι - \dot{m}} [ k ] = \frac{1}{{J}_{m}} ( {η}_{G} {k}_{t} i [ k ] - {b}_{m} {ω}_{i} [ k ] - s a t ( \frac{{τ}_{f}}{{ω}_{friction}} {ω}_{i} [ k ] , - {τ}_{f} , {τ}_{f} ) ) .$$

The output of block 908 is input into an integrator limit function of block 910 with the inverse of the positive real number

$${ω}_{{e}_{max}} > 0 , \frac{1}{{ω}_{{e}_{max}}}$$

and eₗᵢₘᵢₜ[k] as additional inputs. The integrator limit function at block 910 assigns a ωᵢ[k] as follows:

$$\dot{{ω}_{ι} [ k ]} = \{ \begin{matrix}\frac{max ( {ω}_{{e}_{max}} - {e}_{limit} [ k ] , 0 )}{{ω}_{{e}_{max}}} \dot{{ω}_{ι - m}} [ k ] , if {e}_{limit} [ k ] \geq 0 ⋀ \dot{{ω}_{ι - m}} [ k ] > 0 \\ \frac{max ( {ω}_{{e}_{max}} + {e}_{limit} [ k ] , 0 )}{{ω}_{{e}_{max}}} \dot{{ω}_{ι - m}} [ k ] , if {e}_{limit} [ k ] < 0 ⋀ \dot{{ω}_{ι - m}} [ k ] < 0 \\ \dot{{ω}_{ι - m} [ k ]} , otherwise\end{matrix} .$$

At block 912, the output of the integrator limit function, ωᵢ[k], is input into an integrator block which outputs ωᵢ[k] such that the output of the mechanical omega estimator is ωᵢ[k]=ωᵢ[k−1]+Ts×ωᵢ[k−1].

FIG. 10 is an angular velocity selector such as the omega selector 802 of FIG. 8. The omega selector 802 may be used to select a best estimate for the angular velocity of the motor when there is no motion detected by the motor encoder and when none of the above-described detectable motor encoder faults have occurred. The omega selector 802 may be a function of the measured angular velocity of the motor, ω_{f}, the voltage, v, the second estimated angular velocity, ωᵢ, a result of the motor encoder fault determination and a determination of whether the motor is moving. At block 1002, δωᵢ is determined as a distance between the measured angular velocity of the motor, ω_{f}, and the second estimated angular velocity, ωᵢ. At block 1004, an absolute value of δωᵢ is determined. A minimum angular velocity, ω_{not moving}, is defined as a minimum detectable threshold for detecting motion of the motor. Then, at block 1006, a selector function takes ω_{f}, ωᵢ, δωᵢ, the result of the motor encoder fault determination and a determination of whether the motor is moving as inputs to determine the selected angular velocity, ωₛ.

The function begins by determining if there is a motor encoder fault detected. A motor encoder fault may be detected by the methods described above with reference to FIG. 7A. If there is a motor encoder fault, the angular velocity, ω, is set to the second estimated angular velocity, ωᵢ, ωₛ=ωᵢ. If there is not a motor encoder fault, the function determines if there is movement of the motor. If there is not movement, the function determines if δωᵢ≤ω_{not moving}, where δωᵢ is a distance between the measured angular velocity of the motor, ω_{f}, and the second estimated angular velocity, ωᵢ. If δωᵢ<ω_{not moving}, then ωₛ=ω_{f}, otherwise, ωₛ=ωᵢ. If there is movement of the motor detected and there is no motor encoder fault, then ωₛ=ω_{f}.

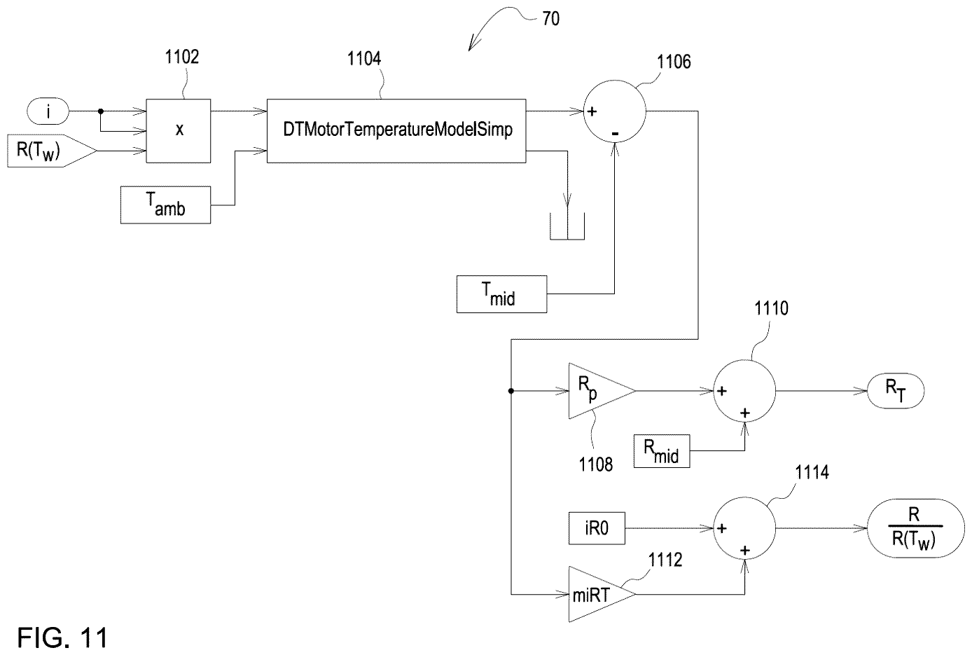

FIG. 11 is a diagram of the DT motor temperature model 70. In at least one example embodiment, the DT motor temperature model 70 may be used to estimate the motor coil resistance, R_{T}. The DT motor temperature model 70 shows how the measured motor current, i, and the estimated motor resistance based on the motor coil temperature, R(T_{w}), are used to compute a thermal power, pₜ=i²R(T_{w}).

In particular, the motor temperature model takes the measured motor current, i, and the motor coil temperature, R(T_{w}), as inputs. At block 1102 the thermal power is determined. In particular, the measured motor current, i, is squared and multiplied by the motor coil temperature, R(T_{w}): i²R(T_{w}). At block 1104, the thermal power and an ambient temperature, T_{amb}, are input into a DT second order motor temperature model which outputs a changing coil temperature, T_{w}, and a motor wall temperature, Tₛ. Further details of the DT second order motor temperature model are described below with reference to FIG. 12.

The changing coil temperate, T_{w}, and the motor wall temperature, Tₛ, may then be used to determine the coil resistance in terms of a thermal temperature coefficient, ρ. In particular, R_{T}=R(1+ρ(T_{w}−T_{mid}+T_{mid}−T_{amb})). In other terms: R_{T}=Rρ(T_{w}−T_{mid})+R_{mid} where R_{mid}=R(1+ρ(T_{mid}−T_{amb})).

In at least one example embodiment, the relationship T_{amb}<T_{mid}<Tᵤₗₜ may be approximated by a first order polynomial fit (with real coefficients iR0 and miRT) for computational efficiency:

$$\frac{R}{R ( {T}_{w} )} = \frac{1}{1 + ρ ( {T}_{w} - {T}_{amb} )} = iR 0 + miRT ( {T}_{w} - {T}_{mid} )$$

where T_{w} ∈[T_{amb},Tᵤₗₜ]. In at least one example embodiment, T_{mid} is a constant real number that is defined such that T_{amb}<T_{mid}<Tᵤₗₜ. For example, T_{mid} may be defined by T_{mid}=0.5*(Tᵤₗₜ−T_{amb}). Tᵤₗₜ is a constant real number that is a maximum temperature for the motor coil. In at least one example embodiment, both T_{mid} and Tᵤₗₜ may be user defined.

In particular, at block 1106, a constant real number, T_{mid}, is subtracted from the changing coil temperature, T_{w}. At block 1108, the output of block 1106 is multiplied by Rρ, resulting in Rρ(T_{w}−T_{mid}). At block 1110, R_{mid} is added to the output of block 1108 resulting in R_{T}=Rρ(T_{w}−T_{mid})+R_{mid} as described above.

At block 1112, the output of block 1106 is multiplied by miRT resulting in miRT(T_{w}−T_{mid}). At block 1114, the output of block 1112 is added to iR0 to obtain

$$\frac{R}{R ( {T}_{w} )}$$

as described above.

FIG. 12 is the DT second order motor temperature model 1104 of FIG. 11. The DT second order motor temperature model may take a measured ambient temperature or an assumed ambient temperature, T_{amb}, as an input to determine the changing coil temperature, T_{w}, and the motor wall temperature, Tₛ. A first fundamental relationship defined by the DT second order motor temperatures model is:

$${C}_{th 1} \dot{{T}_{w}} ( t ) = - \frac{{T}_{w} ( t ) - {T}_{s} ( t )}{{R}_{th 1}} + p ( t )$$

and a second fundamental relationship defined by the DT second order motor temperatures model is:

$${C}_{th 2} \dot{{T}_{s}} ( t ) = \frac{{T}_{w} ( t ) - {T}_{s} ( t )}{{R}_{th 1}} - \frac{{T}_{s} ( t ) - {T}_{amb} ( t )}{{R}_{th 2}}$$

where Cₜₕ₁ is a winding thermal capacitance or an inverse of the heat capacity, Cₜₕ₂ is a housing thermal capacitance or an inverse of the heat capacity, Rₜₕ₁ is a thermal resistance from the winding to the housing, and Rₜₕ₂ is a thermal resistance from the housing to an ambient environment.

At block 1202, the thermal power, pₜ, is added to an output of block 1212 which will be discussed in further detail below. At block 1204, the output of block 1202 is multiplied by

$$\frac{{R}_{th 1}}{{τ}_{w}} .$$

The output of block 1204 is input into a DT integrator initialized with the ambient temperature, T_{amb}, which outputs the changing coil temperature, T_{w} such that (T_{w}[0]=T_{amb}[0]):

$${T}_{w} [ k ] = {T}_{W} [ k - 1 ] + Ts \frac{{R}_{th 1}}{{τ}_{w}} ( {p}_{t} + \frac{1}{{R}_{th 1}} ( {T}_{s} [ k - 1 ] - {T}_{W} [ k - 1 ] ) ) .$$

At block 1214, the changing coil temperature, T_{w}, is multiplied by

$$\frac{1}{{R}_{th 1}} .$$

At block 1216, the output of block 1214 is input into block 1216 with an output of each of block 1226 and block 1224, which will be described in further detail below. At block 1218, the output of block 1216 is multiplied by

$$\frac{{R}_{th 2}}{{τ}_{s}} .$$

At block 1220, the output of block 1218 is input into another DT integrator and initialized with the ambient temperature, T_{amb}, which results in an output of the motor wall temperature, Tₛ[k] such that (Tₛ[0]=T_{amb}[0]) and

$${T}_{s} [ k ] = {T}_{s} [ k - 1 ] + Ts \frac{{R}_{th 2}}{{τ}_{s}} ( \frac{1}{{R}_{th 1}} ( {T}_{W} [ k - 1 ] - {T}_{s} [ k - 1 ] ) - \frac{1}{{γ}_{h} {R}_{th 2}} ( {T}_{s} [ k - 1 ] - {T}_{amb} [ k - 1 ] ) ) .$$

At block 1226, the motor wall temperature, Tₛ, is multiplied by

$$\frac{1}{{R}_{th 1}}$$

and is input into block 1216. At block 1222, the ambient temperature, T_{amb}, is subtracted from the motor wall temperature, Tₛ. At block 1224, the output of block 1222 is multiplied by

$$\frac{1}{{γ}_{h} {R}_{th 2}} ,$$

where γ is a constant as described in further detail below.

At block 1208, the changing coil temperature, T_{w}, is multiplied by

$$\frac{1}{{R}_{th 1}}$$

and is input into block 1212. At block 1210, the motor wall temperature, Tₛ, is multiplied by

$$\frac{1}{{R}_{th 1}}$$

and is input into block 1212.

The changing coil temperate, T_{w}, and the motor wall temperature, Tₛ, may be determined by:

$$[ \begin{matrix}{T}_{w} [ k ] \\ {T}_{s} [ k ]\end{matrix} ] = [ \begin{matrix}( 1 - \frac{Ts}{{τ}_{w}} ) & \frac{Ts}{{τ}_{w}} \\ \frac{Ts}{{τ}_{s}} \frac{{R}_{th 2}}{{R}_{th 1}} & ( 1 - \frac{Ts}{{γ}_{h} {τ}_{s}} - \frac{Ts}{{τ}_{s}} \frac{{R}_{th 2}}{{R}_{th 1}} )\end{matrix} ] [ \begin{matrix}{T}_{w} [ k - 1 ] \\ {T}_{s} [ k - 1 ]\end{matrix} ] + [ \begin{matrix}\frac{{Tsp}_{t} [ k - 1 ]}{{c}_{th 1}} \\ \frac{Ts}{{γ}_{h} {τ}_{s}} {T}_{amb} [ k - 1 ]\end{matrix} ]$$

where τ_{w} is a thermal time constant of the winding such that τ_{w}=Rₜₕ₁Cₜₕ₁, τₛ is a thermal time constant of the motor such that τₛ=Rₜₕ₂ Cₜₕ₂, and γ is a constant, γ∈(0,1], that is used to account for heat loss through the mount of the motor. If γ=1, the motor may be mounted on an insulated plastic plate where a metallic conductive plate may allow γ to be as low as about 0.2.

In particular, the thermal power, pₜ, may be input into the DT second order motor temperature model 1104

FIG. 13 is a diagram of the DC motor fault accommodation algorithm 72. In at least one example embodiment, the angular velocity residual, r_{ω}, and the motor encoder fault determination described above with reference to FIG. 7A are used to detect if the motor encoder is in a fault state. If a fault is detected, an estimated angular position, θᵥ, is used for motor position and velocity control. A function for motor fault detection and accommodation may take a measured motor position, θ, the estimated angular position, θᵥ, the angular velocity residual, r_{ω}, the motor wall temperature, Tₛ, a first constant positive real number t_{fault}, a second constant positive real number r_{ω}_{_{fault}}, an enabled variable, an enable fault accommodation variable, enable_fault_accommodation, and a motor encoder fault variable as inputs to a motor fault detection and accommodation function 1302. The motor fault detection and accommodation function 1302 outputs a selected angular position, θ_{fb}, and a fault determination. The first constant positive real number t_{fault} may be a number in seconds that may be used to establish a desired fault detection time. The second constant positive real number r_{ω}_{_{fault}} may allow for detecting encoder faults while minimizing a rate of false positive detections of encoder faults. The function begins by defining persistent variables of a fault counter, k, a threshold fault variable, k_{fault}, a fault flag, in_{fault}, and θₒ. Then, if k is empty or if the enabled variable is false, the following definitions are set: k=uint32(0); k_{fault}=uint32(t_{fault}/Ts); in_{fault}=false; and θₒ=single(0). In at least one example embodiment, t_{fault} is defined as 0.1 seconds and r_{ω}_{_{fault}} is defined as half of a maximum motor angular velocity such as 523.6 rad/s for example.

Next, the function will determine if the fault counter, k, should be incremented or decremented. If there is a residual fault or a detectable motor fault, eQEPFault, then the fault counter, k, is increased by one: if (k<k_{fault})&& (eQEPFault∥|r_{ω}>r_{ω}_{_{fault}})) then k=k+uint32(1). If there is no fault state detected, then the fault counter, k, is decreased by one: elseif (k>uint32(0))&& in_{fault}=false then k=k−uint32(1).

Then, the function will determine if a detected fault should persist or if the system is not in a fault state and the in_{fault} variable should be updated. In particular, if the fault counter is greater than the threshold fault variable and the fault flag is currently set to false, then the fault flag should be updated to true to indicate that there is a fault: if(k≥k_{fault}) && in_{fault}==false, then in_{fault}=true. Otherwise, if the fault counter equals zero, then the fault flag should be updated to false: elseif(k==int32(0)), then θₒ=θₘ−θₘᵣ and in_{fault}=false.

Finally the function will determine whether to use the estimated angular position or the sensed angular position. If the fault flag is true and fault accommodation is enabled, then the estimated angular position should be used for the motor position: if in_{fault}==true && enable_fault_accommodation==true, then θ_{fb}=θᵥ+θ₀ where if(θᵣ_{ᵣₑₛₑₜ}), θ₀=single(0). In at least one example embodiment, θᵣ_{ᵣₑₛₑₜ} is true if the encoder count resets to zero. This is defined to handle a case when the encoder count reaches either a minimum or a maximum value and has to be reset back to zero. Otherwise, the motor encoder feedback will continue to be used for the motor position: θ_{fb}=0. The function concludes by setting the fault determination equal to the fault flag, in_{fault}.

In FIG. 13 the output, ‘fault accommodate’, is true if the Boolean constant enable_fault_accomodation is true and fault is true as determined by the AND block 1304. Otherwise, the output is false. Block 1306 is a switch which passes the ‘encoder reset’ value when the output from 1304 is false, otherwise it passes the ‘theta_V reset’ pulse which is generated by the back-emf angle estimate θ_{V}. The system of 1310 (unit delay block), 1312 (NOT block), 1314 (three input AND block), 1316 (NOT block), and 1308 (three port OR block) are used to create a theta reset pulse when ‘fault accommodate’ becomes active. An example of the fault transitioning from FALSE to TRUE and then back to FALSE is given with the appropriate outputs in order to generate to theta_reset pulses to transition control from using feedback from the motor encoder, θₘ, to the back emf model of the motor position, θ_{V}.

| | enable_fault_accom- | | | | | | | | |
|---|---|---|---|---|---|---|---|---|---|
| k | modation | fault | 1310 | 1312 | 1316 | 1318 | 1314 | 1306 | theta_reset |
| 0 | TRUE | FALSE | FALSE | TRUE | TRUE | FALSE | FALSE | FALSE | FALSE |
| 1 | TRUE | TRUE | FALSE | TRUE | FALSE | FALSE | TRUE | FALSE | TRUE |
| 2 | TRUE | TRUE | TRUE | FALSE | FALSE | FALSE | FALSE | FALSE | FALSE |
| 3 | TRUE | TRUE | TRUE | FALSE | FALSE | FALSE | FALSE | FALSE | FALSE |
| 4 | TRUE | FALSE | TRUE | FALSE | TRUE | TRUE | FALSE | FALSE | TRUE |
| 5 | TRUE | FALSE | FALSE | TRUE | TRUE | FALSE | FALSE | FALSE | FALSE |
| 6 | TRUE | FALSE | FALSE | TRUE | TRUE | FALSE | FALSE | FALSE | FALSE |

The above-described system provides an improvement over traditional fault accommodation systems because the estimate of the angular velocity is independent of loads applied in the system. By being independent of applied loads, the accuracy of the estimated angular velocity may be improved because the system is less prone to false positives if a significant load disturbance is encountered. The system is also able to detect an unplugged motor encoder which is a relatively common system fault. The system is also able to detect that movement of the motor is detected even when there is a motor encoder fault which allows a motor encoder fault to be narrowed down to determine which one of the two motor encoder pins is in a stuck state. This allows an angular velocity selector as described in FIG. 10 to be used to detect if the motor encoder is not working or if the motor is truly moving at a very slow speed. Further, by using models that include static friction, an estimate of the angular velocity can be used if a motor encoder fault is detected and the system can remain single fault safe by being able to identify a motor encoder open or short circuit fault. Finally, in order to remain single fault safe the system has a residual generator to detect both open and short circuits in the system. This hybrid approach to fault detection and accommodation creates a more robust and resilient system which improves overall system availability while remaining fail safe.

Example embodiments have been disclosed herein, it should be understood that other variations may be possible. Such variations are not to be regarded as a departure from the spirit and scope of the present disclosure, and all such modifications as would be obvious to one skilled in the art are intended to be included within the scope of the following claims.

### Non-Limiting Illustrative Embodiments

The following is a list of non-limiting illustrative embodiments disclosed herein:

Illustrative embodiment 1 includes a system for fault accommodation in a motor. The system comprises at least one memory configured to store instructions and at least one processor configured to execute the instructions and cause the system to determine an estimated angular velocity of the motor and an estimated angular position of the motor, detect a sensor fault of a motor encoder, and in response to the sensor fault being detected, detect at least one additional fault with at least one of the estimated angular velocity or the estimated angular position.

Illustrative embodiment 2 includes the system of illustrative embodiment 1, wherein the at least one processor is further configured to cause the system to determine an estimated coil resistance of the motor based on a measured motor coil temperature and an ambient temperature.

Illustrative embodiment 3 includes the system of illustrative embodiment 1, wherein the estimated angular velocity is a first estimated angular velocity. The first estimated angular velocity is determined based on the estimated coil resistance of the motor, a measured motor voltage, a measured motor current, a time derivative of a filtered motor current, and an inductance

Illustrative embodiment 4 includes the system of any one of illustrative embodiments 1, 2, and 3, wherein the at least one processor is further configured to cause the system to obtain a sensed angular velocity of the motor by differentiating the sensed angular position of the motor.

Illustrative embodiment 5 includes the system of illustrative embodiment 4, wherein the at least one processor is further configured to cause the system to determine an angular position residual based on the sensed angular position of the motor encoder and the estimated angular position of the motor encoder.

Illustrative embodiment 6 includes the system of any one of illustrative embodiments 4 and 5, wherein the at least one processor is further configured to cause the system to determine an angular velocity residual based on the sensed angular velocity of the motor and the estimated angular velocity of the motor.

Illustrative embodiment 7 includes the system of illustrative embodiment 6, wherein the motor encoder includes a first pin, a second pin, and an index pin and wherein the processor is further configured to cause the system to detect an electrical fault based on a state of one or more of the first pin, the second pin, or the index pin.

Illustrative embodiment 8 includes the system of illustrative embodiment 7, wherein the estimated angular velocity is a second estimated angular velocity, the second estimated angular velocity being determined based on a measured current and a model of a motor plant in response to an electrical fault being detected.

Illustrative embodiment 9 includes the system of any one of illustrative embodiments 7 and 8, wherein the at least one additional fault is a fault state of the motor encoder, the fault state of the motor encoder being detected based on the angular velocity residual or detection of the electrical fault.

Illustrative embodiment 10 includes the system of illustrative embodiment 9, wherein the estimated angular position of the motor encoder is used for motor position and velocity control in response to the at least one additional fault being a fault state of the motor encoder.

Illustrative embodiment 11 includes the system of any one of illustrative embodiments 4, 5, 6, 7, 8, 9, and 10, wherein the at least one processor is further configured to cause the system to set a minimum velocity as a threshold for detecting motion of the motor and determine a selected angular velocity when no motion of the motor is detected.

Illustrative embodiment 12 includes the system of illustrative embodiment 11, wherein the selected angular velocity is the estimated angular velocity in response to determining that the motor encoder is broken and is the sensed angular velocity in response to the sensed angular velocity agreeing with the estimated angular velocity.

Illustrative embodiment 13 includes the system of any one of illustrative embodiments 1, 2, 3, 4, 5, 6, 7, 8, 9, 10, 11, and 12, wherein the at least one processor is further configured to cause the system to determine a current residual based on a sensed current and an estimated current of the motor.

Illustrative embodiment 14 includes the system of illustrative embodiment 13, wherein the at least one additional fault is an open circuit, the open circuit being detected based on the current residual, a minimum allowable angular velocity threshold, and a motor resistance fault.

Illustrative embodiment 15 includes the system of any one of illustrative embodiments 13 and 14, wherein the at least one additional fault is a short circuit, the short circuit being detected based on the current residual and a motor resistance fault.

Illustrative embodiment 16 includes the system of any one of illustrative embodiments 1, 2, 3, 4, 5, 6, 7, 8, 9, 10, 11, 12, 13, 14, and 15, wherein the motor is a direct current (“DC”) motor.

Illustrative embodiment 17 includes the system of any one of illustrative embodiments 1, 2, 3, 4, 5, 6, 7, 8, 9, 10, 11, 12, 13, 14, 15, and 16, wherein the estimated angular velocity is independent of loads applied in the system.

Illustrative embodiment 18 includes a method for fault accommodation in a motor. The method comprises determining an estimated angular velocity of the motor and an estimated angular position of the motor, detecting a sensor fault of a motor encoder, and in response to the sensor fault being detected, detecting at least one additional fault with at least one of the estimated angular velocity or the estimated angular position.

Illustrative embodiment 19 includes the method of illustrative embodiment 18, further comprising determining an estimated coil resistance of the motor based on a measured motor coil temperature and an ambient temperature, wherein the estimated angular velocity is a first estimated angular velocity, the first estimated angular velocity being determined based on the estimated coil resistance of the motor, a measured motor voltage, a measured motor current, a time derivative of a filtered motor current, and an inductance.

Illustrative embodiment 20 includes the method of any one of illustrative embodiments 18 and 19, further comprising obtaining a sensed angular velocity of the motor and a sensed angular position of the motor, determining an angular velocity residual based on the sensed angular velocity of the motor and the estimated angular velocity of the motor, and determining an angular position residual based on the sensed angular position of the motor encoder and the estimated angular position of the motor encoder.

Illustrative embodiment 21 includes the method of illustrative embodiment 20, wherein the motor encoder includes a first pin, a second pin, and an index pin and wherein the method further comprises detecting an electrical fault based on a state of one or more of the first pin, the second pin, or the index pin.

Illustrative embodiment 22 includes the method of illustrative embodiment 21, wherein the estimated angular velocity is a second estimated angular velocity, the second estimated angular velocity being determined based on a measured current and a model of a motor plant in response to an electrical fault being detected.

Illustrative embodiment 23 includes the method of any one of illustrative embodiments 21 and 22, wherein the at least one additional fault is a fault state of the motor encoder, the fault state of the motor encoder being detected based on the angular velocity residual or detection of the electrical fault.

Illustrative embodiment 24 includes the method of illustrative embodiment 23, wherein the estimated angular position of the motor encoder is used for motor position and velocity control in response to the at least one additional fault being a fault state of the motor encoder.

Illustrative embodiment 25 includes the method of any one of illustrative embodiments 20, 21, 22, 23, and 24, further comprising setting a minimum velocity as a threshold for detecting motion of the motor and determining a selected angular velocity when no motion of the motor is detected, wherein the selected angular velocity is the estimated angular velocity in response to determining that the motor encoder is broken and is the sensed angular velocity in response to the sensed angular velocity agreeing with the estimated angular velocity.

Illustrative embodiment 26 includes the method of any one of illustrative embodiments 18, 19, 20, 21, 22, 23, 24, and 25, further comprising determining a current residual based on a sensed current and an estimated current of the motor, wherein in response to the at least one additional fault being an open circuit, detecting the open circuit based on the current residual, a minimum allowable angular velocity threshold, and a motor resistance fault and in response to the at least one additional fault being a short circuit, detecting the short circuit based on the current residual and a motor resistance fault.

1. A system for fault accommodation in a motor, the system comprising:
at least one memory configured to store instructions; and
at least one processor configured to execute the instructions and cause the system to,
determine an estimated angular velocity of the motor and an estimated angular position of the motor,
detect a sensor fault of a motor encoder, and
in response to the sensor fault being detected, detect at least one additional fault with at least one of the estimated angular velocity or the estimated angular position.

2. The system of claim 1, wherein the at least one processor is further configured to cause the system to
determine an estimated coil resistance of the motor based on a measured motor coil temperature and an ambient temperature.

3. The system of claim 2, wherein the estimated angular velocity is a first estimated angular velocity, the first estimated angular velocity being determined based on the estimated coil resistance of the motor, a measured motor voltage, a measured motor current, a time derivative of a filtered motor current, and an inductance.

4. The system of claim 1, wherein the at least one processor is further configured to cause the system to
obtain a sensed angular velocity of the motor by differentiating the sensed angular position of the motor.

5. The system of claim 4, wherein the at least one processor is further configured to cause the system to
determine an angular position residual based on the sensed angular position of the motor encoder and the estimated angular position of the motor encoder.

6. The system of claim 4, wherein the at least one processor is further configured to cause the system to
determine an angular velocity residual based on the sensed angular velocity of the motor and the estimated angular velocity of the motor.

7. The system of claim 6, wherein the motor encoder includes a first pin, a second pin, and an index pin and wherein the processor is further configured to cause the system to
detect an electrical fault based on a state of one or more of the first pin, the second pin, or the index pin.

8. The system of claim 7, wherein the estimated angular velocity is a second estimated angular velocity, the second estimated angular velocity being determined based on a measured current and a model of a motor plant in response to an electrical fault being detected.

9. The system of claim 7, wherein the at least one additional fault is a fault state of the motor encoder, the fault state of the motor encoder being detected based on the angular velocity residual or detection of the electrical fault.

10. The system of claim 9, wherein the estimated angular position of the motor encoder is used for motor position and velocity control in response to the at least one additional fault being a fault state of the motor encoder.

11. The system of claim 4, wherein the at least one processor is further configured to cause the system to
set a minimum velocity as a threshold for detecting motion of the motor; and
determine a selected angular velocity when no motion of the motor is detected.

12. The system of claim 11, wherein the selected angular velocity is the estimated angular velocity in response to determining that the motor encoder is broken and is the sensed angular velocity in response to the sensed angular velocity agreeing with the estimated angular velocity.

13. The system of claim 1, wherein the at least one processor is further configured to cause the system to
determine a current residual based on a sensed current and an estimated current of the motor.

14. The system of claim 13, wherein the at least one additional fault is an open circuit, the open circuit being detected based on the current residual, a minimum allowable angular velocity threshold, and a motor resistance fault.

15. The system of claim 13, wherein the at least one additional fault is a short circuit, the short circuit being detected based on the current residual and a motor resistance fault.

16. The system of claim 1, wherein the motor is a direct current (“DC”) motor.

17. The system of claim 1, wherein the estimated angular velocity is independent of loads applied in the system.

18. A method for fault accommodation in a motor, the method comprising:
determining an estimated angular velocity of the motor and an estimated angular position of the motor;
detecting a sensor fault of a motor encoder; and
in response to the sensor fault being detected, detecting at least one additional fault with at least one of the estimated angular velocity or the estimated angular position.

19. The method of claim 18, further comprising:
determining an estimated coil resistance of the motor based on a measured motor coil temperature and an ambient temperature,
wherein the estimated angular velocity is a first estimated angular velocity, the first estimated angular velocity being determined based on the estimated coil resistance of the motor, a measured motor voltage, a measured motor current, a time derivative of a filtered motor current, and an inductance.

20. The method of claim 18, further comprising:
obtaining a sensed angular velocity of the motor and a sensed angular position of the motor;
determining an angular velocity residual based on the sensed angular velocity of the motor and the estimated angular velocity of the motor; and
determining an angular position residual based on the sensed angular position of the motor encoder and the estimated angular position of the motor encoder.

21. The method of claim 20, wherein the motor encoder includes a first pin, a second pin, and an index pin and wherein the method further comprises:
detecting an electrical fault based on a state of one or more of the first pin, the second pin, or the index pin.

22. The method of claim 21, wherein the estimated angular velocity is a second estimated angular velocity, the second estimated angular velocity being determined based on a measured current and a model of a motor plant in response to an electrical fault being detected.

23. The method of claim 21, wherein the at least one additional fault is a fault state of the motor encoder, the fault state of the motor encoder being detected based on the angular velocity residual or detection of the electrical fault.

24. The method of claim 23, wherein the estimated angular position of the motor encoder is used for motor position and velocity control in response to the at least one additional fault being a fault state of the motor encoder.

25. The method of claim 20, further comprising:
setting a minimum velocity as a threshold for detecting motion of the motor; and
determining a selected angular velocity when no motion of the motor is detected,
wherein the selected angular velocity is the estimated angular velocity in response to determining that the motor encoder is broken and is the sensed angular velocity in response to the sensed angular velocity agreeing with the estimated angular velocity.

26. The method of claim 18, further comprising:
determining a current residual based on a sensed current and an estimated current of the motor, wherein
in response to the at least one additional fault being an open circuit, detecting the open circuit based on the current residual, a minimum allowable angular velocity threshold, and a motor resistance fault, and
in response to the at least one additional fault being a short circuit, detecting the short circuit based on the current residual and a motor resistance fault.

27. The system of claim 2, further comprising inputting the ambient temperature and a measured current into a second order motor temperature model to determine the coil resistance.
